(19) United States
(12) Patent Application Publication
(10) Pub. No.: US 2025/0081674 A1
(43) Pub. Date: Mar. 6, 2025

(54) LIGHT EMITTING ELEMENT AND DISPLAY DEVICE COMPRISING THE SAME

(71) Applicant: LG Display Co., Ltd., Seoul (KR)

(72) Inventors: Jihyun KOO, Seoul (KR); Kiyong HONG, Paju-si (KR); Kiyoung SONG, Paju-si (KR); Byungyeon CHOI, Goyang-si (KR)

(73) Assignee: LG Display Co., Ltd., Seoul (KR)

(21) Appl. No.: 18/744,207

(22) Filed: Jun. 14, 2024

(30) Foreign Application Priority Data
Aug. 31, 2023 (KR) 10-2023-0115702

(51) Int. Cl. H01L 33/20; H01L 25/16

(52) U.S. Cl. CPC H10H 20/819; H01L 25/167

(57) ABSTRACT

A light emitting element can include a first semiconductor layer, a first electrode disposed on the first semiconductor layer; an active layer disposed on the first semiconductor layer, the active layer being spaced apart from the first electrode; a second semiconductor layer disposed on the active layer; and a second electrode disposed on the second semiconductor layer, in which a first part of the active layer between the first electrode and the second electrode is wider than a second part of the active layer between the first electrode and the second electrode.

### CROSS-REFERENCE TO RELATED APPLICATIONS

This application claims the priority to Korean Patent Application No. 10-2023-0115702 filed on Aug. 31, 2023, in the Republic of Korea, the entirety of which is incorporated herein by reference into the present application.

### BACKGROUND

### Field

The present disclosure relates to a light emitting element and a display device including the same, and more particularly, to a light emitting diode (LED) and a display device using the same.

### Description of the Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions, and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

Also, since the LED can be very small and produced in high quantities, defects during the manufacturing process can occur even from slight variations (e.g., such as a slight misalignment), which can narrow the viewing angle and impair image quality.

Thus, a need exists for a light emitting device that has a configuration that is resistant to variations that may occur during manufacturing processes, improves manufacturing yields, has increased brightness and improved viewing angles.

### SUMMARY OF THE DISCLOSURE

An object to be achieved by the present disclosure is to provide a light emitting element in which a deviation of an inclination angle of a side surface of the light emitting element is reduced and a display device including the same.

Another object to be achieved by the present disclosure is to provide a light emitting element with reduced luminance deviation depending on a viewing angle and a display device including the same.

Objects of the present disclosure are not limited to the above-mentioned objects, and other objects, which are not mentioned above, can be clearly understood by those skilled in the art from the following descriptions.

According to an aspect of the present disclosure, there is provided a light emitting element. The light emitting element includes a first semiconductor layer, a first electrode and an active layer disposed on the first semiconductor layer, the first electrode being spaced apart from the active layer, a second semiconductor layer on the active layer, and a second electrode on the second semiconductor layer, in which the active layer includes, a plurality of first parts having a first width in a width direction, and a second part disposed between at least two of the plurality of first parts and the second part having a second width smaller than the first width in the width direction.

According to another aspect of the present disclosure, there is provided a display device. The display device includes a substrate, and a plurality of light emitting elements disposed on the substrate. Each of the plurality of light emitting elements includes a first semiconductor layer, a first electrode and an active layer disposed on the first semiconductor layer, a second semiconductor layer on the active layer, and a second electrode disposed on the second semiconductor layer, the second electrode being apart from the first electrode. The active layer includes a first part having a first width, and a second part having a same width as a width of the first part in longitudinal direction and having a second width smaller than the first width in a width direction.

Other detailed matters of the example embodiments are included in the detailed description and the drawings.

According to the present disclosure, even if a process deviation occurs, it is possible to uniformly form the inclination angle of the side surface of the light emitting element.

According to the present disclosure, it is possible to reduce the occurrence of color difference due to the change in viewing angle.

According to the present disclosure, it is possible to minimize the occurrence of mura due to the change in viewing angle.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic plan view of a light emitting element according to an example embodiment of the present disclosure;

FIGS. 2A to 2C are cross-sectional views of a light emitting element according to an example embodiment of the present disclosure;

FIGS. 3A and 3B are process diagrams illustrating a method of manufacturing a light emitting element according to an example embodiment of the present disclosure;

FIG. 4 is a schematic plan view of a light emitting element according to another example embodiment of the present disclosure;

FIGS. 5A and 5B are cross-sectional views of a light emitting element according to another example embodiment of the present disclosure;

FIGS. 6A and 6B are schematic plan views of a light emitting element according to still another example embodiment of the present disclosure;

FIGS. 7A and 7B are schematic plan views of a light emitting element according to still another example embodiment of the present disclosure;

FIGS. 8A and 8B are schematic plan views of a light emitting element according to still another example embodiment of the present disclosure;

FIGS. 9A and 9B are schematic plan views of a light emitting element according to still another example embodiment of the present disclosure;

FIG. 10 is a schematic configuration diagram of a display device according to an example embodiment of the present disclosure; and

FIG. 11 is a cross-sectional view of a pixel area of a display device according to an example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only.” Any references to singular can include plural unless expressly stated otherwise.

Components are interpreted to include an ordinary error range even if not expressly stated.

When the position relation between two parts is described using the terms such as “on,” “above,” “below,” and “next,” one or more parts can be positioned between the two parts unless the terms are used with the term “immediately” or “directly.”

When an element or layer is disposed “on” another element or layer, another layer or another element can be interposed directly on the other element or therebetween.

Although the terms “first,” “second,” and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a light emitting element and a display device according to example embodiments of the present disclosure will be described in detail with reference to accompanying drawings.

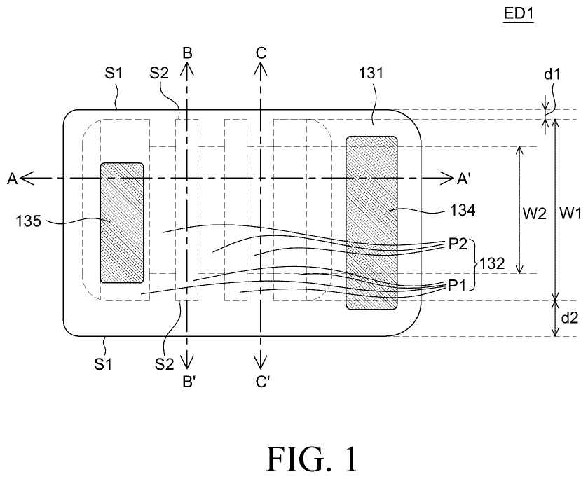

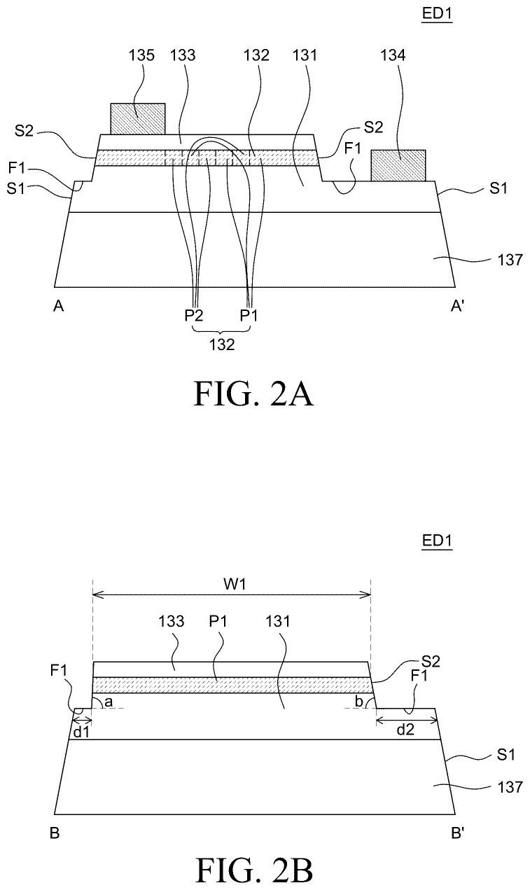

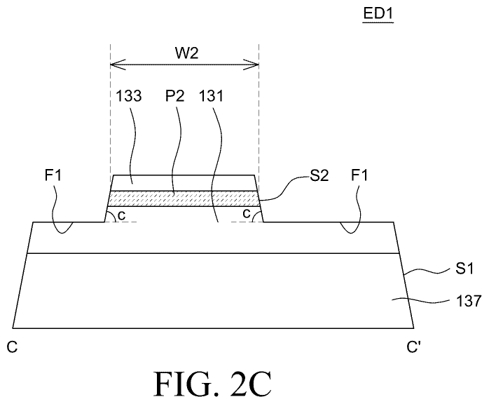

FIG. 1 is a schematic plan view of a light emitting element according to an example embodiment of the present disclosure. FIGS. 2A to 2C are cross-sectional views of a light emitting element according to an example embodiment of the present disclosure. In FIG. 1, for convenience of illustration, only a first semiconductor layer 131, an active layer 132, a first electrode 134, and a second electrode 135 of a light emitting element ED1 are illustrated. FIG. 2A is a cross-sectional view taken along line A-A′ of FIG. 1. FIG. 2B is a cross-sectional view taken along line B-B′ of FIG. 1. FIG. 2C is a cross-sectional view taken along line C-C′ of FIG. 1.

Referring to FIGS. 1 to 2C, the plurality of light emitting elements ED1 include a base layer 137, the first semiconductor layer 131, the active layer 132, a second semiconductor layer 133, the first electrode 134, and the second electrode 135.

The plurality of light emitting elements ED1 can be formed in various structures such as lateral, vertical, and flip chip. The lateral light emitting element includes a first electrode and a second electrode disposed laterally on both sides of the active layer. The vertical light emitting element includes the first electrode and the second electrode disposed on upper and lower sides of the active layer. The flip chip light emitting element has substantially the same structure as the lateral light emitting element. The lateral light emitting element has the first electrode and the second electrode disposed laterally on the upper side of the active layer, while the flip chip light emitting element has the first electrode and the second electrode disposed laterally on the lower side of the active layer. Hereinafter, the description will be made on the assumption that the plurality of light emitting elements ED1 has a lateral structure, but the type of the plurality of light emitting elements ED1 is not limited thereto.

The base layer 137 can be formed of an undoped semiconductor material. For example, the base layer 137 can be formed of gallium nitride (GaN), indium aluminum phosphide (InAlP), or gallium arsenide (GaAs), but is not limited thereto.

The first semiconductor layer 131 is disposed above the base layer 137. The first semiconductor layer 131 can be a layer formed by doping n-type and p-type impurities into a specific material. For example, the first semiconductor layer 131 can be the layer formed by doping n-type and p-type impurities into materials such as gallium nitride (GaN), indium aluminum phosphide (InAlP), and gallium arsenide (GaAs). Here, the p-type impurities can be magnesium, zinc (Zn), beryllium (Be), or the like, and the n-type impurities can be silicon (Si), germanium, tin (Sn), or the like, but are not limited thereto. In the present disclosure, the first semiconductor layer 131 is defined as an n-type semiconductor layer doped with the n-type impurities but is not limited thereto.

Meanwhile, a portion of the first semiconductor layer 131 can protrude or extend to an outside of the second semiconductor layer 133 and the active layer 132 and can be exposed from the second semiconductor layer 133 and the active layer 132. In this situation, a top surface of the first semiconductor layer 131 protruding or extending to the outside of the second semiconductor layer 133 and the active layer 132 can be defined as a first plane F1 of the light emitting element ED1.

In this situation, the first plane F1 can be shaped to surround outer periphery areas of the active layer 132 and the second semiconductor layer 133. In addition, a side surface of the light emitting element ED1 extending downward from the first plane F1 can be defined as a first side surface S1. As illustrated in FIGS. 2A to 2C, the first side surface S1 can refer to the side surfaces of the first semiconductor layer 131 and the base layer 137 and is disposed below the first plane F1.

The first semiconductor layer 131 can have a constant width in a width direction at a portion except for a corner part. Meanwhile, as illustrated in FIG. 1, corner parts of the first semiconductor layer 131, the active layer 132, and the second semiconductor layer 133 can have a round shape (e.g., rounded corners). In this regard, when driving the light emitting element ED1, to suppress a current from being concentrated in the corner part of the light emitting element ED1, some areas of the first semiconductor layer 131, the active layer 132, and the second semiconductor layer 133, which are disposed at the corner part of the light emitting element ED1, can be removed, but embodiments are not limited thereto.

The active layer 132 and the second semiconductor layer 133 are disposed on the first semiconductor layer 131.

The entire active layer 132 and second semiconductor layer 133 can overlap with the first semiconductor layer 131, and the entire second semiconductor layer 133 can overlap with the active layer 132. In addition, only a portion of the first semiconductor layer 131 can overlap with the active layer 132 and the second semiconductor layer 133.

In this situation, a portion of the first semiconductor layer 131 that overlaps with the first semiconductor layer 131 and the active layer 132 and the second semiconductor layer 133 disposed on the first semiconductor layer 131 can be referred to as a MESA part (e.g., a raised portion of 131 having a mesa shape or a tapered shaped).

Meanwhile, the side surface of the light emitting element ED1 extending from the first plane F1 to extend upward can be defined as a second side surface S2 and can be composed of the side surface of the first semiconductor layer 131, the side surface of the active layer 132, and the side surface of the second semiconductor layer 133. The second side surface S2 can be disposed to be inclined with respect to the first plane F1. In this situation, the second side surface S2 can be the same as a side surface of the MESA part.

The active layer 132 can be disposed on the first semiconductor layer 131 to be spaced apart from the first electrode 134. The active layer 132 can emit light by receiving holes and electrons from the first semiconductor layer 131 and the second semiconductor layer 133. The active layer 132 can be formed of a single-layer or multi-quantum well (MQW) structure, and can be formed of, e.g., indium gallium nitride (InGaN), gallium nitride (GaN), or the like, but is not limited thereto.

Referring to FIG. 1, the active layer 132 can include a plurality of first parts P1 having a first width W1 in the width direction, and a plurality of second parts P2 disposed between the plurality of first parts P1 and having a second width W2 smaller than the first width W1 in the width direction. The plurality of second parts P2 are disposed, and the plurality of first parts P1 and the plurality of second parts P2 can be alternately disposed. Meanwhile, the number of first parts P1 and the number of second side parts P2 illustrated in FIG. 1 are only examples and are not limited thereto.

At least a portion of the second side surface S2 of the second part P2 can be disposed inside the second side surface S2 of the first part P1. That is, as illustrated in FIG. 1, the second side surface S2 of the first part P1 can be disposed more adjacent to the first side surface S1 than the second side surface S2 of the second part P2, and the second side surface S2 of the second part P2 can be disposed adjacent to a center of the light emitting element ED1. In other words, the outer side edges of the second parts P2 can be located farther outside than the outer side edges of the first parts P1 (e.g., second parts P2 are wider than first parts P1). Accordingly, as illustrated in FIGS. 2B and 2C, a distance W1 between the second side surfaces S2 facing in the width direction in the plurality of first parts P1 can be longer than a distance W2 between the second surfaces S2 facing in the width direction in the second part P2 (W1>W2).

Meanwhile, as illustrated in FIG. 1, the active layer 132 can be disposed to be biased toward a B side of the B side and a B′ side which are the width direction. In this situation, as illustrated in FIG. 2B, a distance d1 between the second side surface S2 disposed toward the B side and the first side surface S1 in the first part P1 can be smaller than a distance d2 between the second side surface S2 disposed toward the B′ side and the first side surface S1 in the first part P1 (e.g., d1<d2).

Meanwhile, the distance between the second side surface S2 and the first side surface S1 in the first part P1 can refer to the shortest distance between the first side surface S1 and the second side surface S2 disposed on the light emitting element ED1. Accordingly, the distance d1 between the second side surface S2 disposed on the B side and the first side surface S1 in the first part P1, which is the shortest distance between the first side surface S1 and the second side surface S2 on one side in the width direction, can be smaller than the distance d2 between the second side surface S2 disposed on the B′ side and the first side surface S1 in the first part P1, which is the shortest distance between the first side surface S1 and the second side surface S2 on the other side. For example, as shown in FIG. 1, the active layer 132 can be aligned slightly off center (e.g., closer to the B side than the B′ side).

Meanwhile, the second side surface S2 of the first part P1 can include at least one surface having a different inclination angle. For example, the inclination angle of the second side surface S2 of the first part P1 on one side can be larger than that of the second side surface S2 of the first part P1 on the other side, while the inclination angle of the second side surface S2 of the second part P2 on one side can be the same as that of the second side surface S2 of the second part P2 on the other side. That is, as shown in FIG. 2B, an inclination angle a of the second side surface S2 disposed on the B side is larger than an inclination angle b of the second side surface S2 disposed on the B′ side (e.g., inclination angle a is steeper or more straight than inclination angle b), while in FIG. 2C, an inclination angle c of the second side surface S2 disposed on a C side can be the same as the inclination angle c of the second side surface S2 disposed on a C′ side.

Meanwhile, in FIG. 1, a width of the first part P1 and a width of the second part P2 in longitudinal direction, for example, in the x-direction are illustrated to be the same but may not be limited thereto.

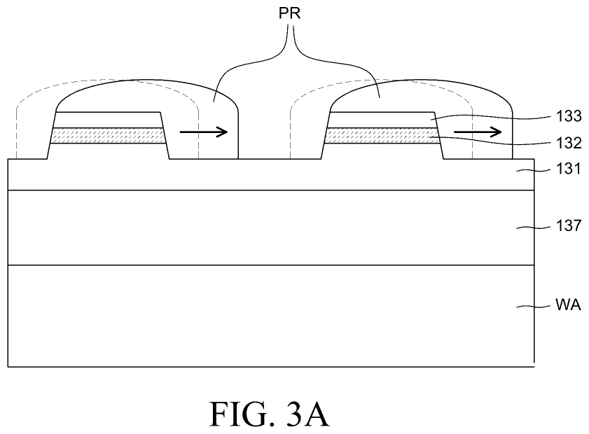

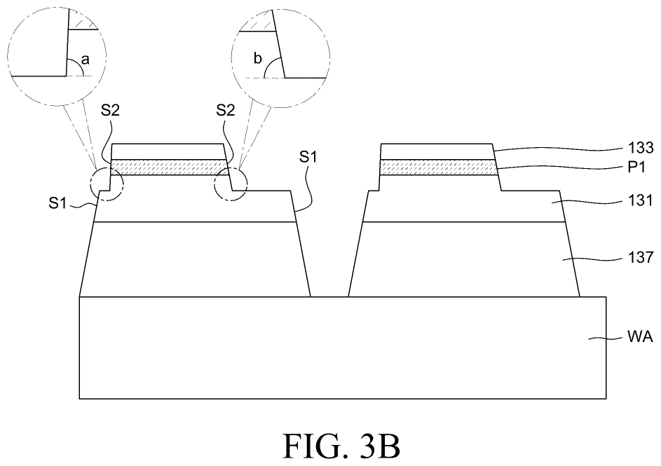

A more detailed description of the second side surface S2 of the first part P1 and the second side surface S2 of the second part P2 will be described below with reference to FIGS. 3A and 3B.

The second semiconductor layer 133 is disposed above the active layer 132. The second semiconductor layer 133 can be a layer formed by doping n-type and p-type impurities into a specific material. For example, the second semiconductor layer 133 can be the layer formed by doping n-type and p-type impurities into materials such as gallium nitride (GaN), indium aluminum phosphide (InAlP), and gallium arsenide (GaAs). In addition, the p-type impurities can be magnesium, zinc (Zn), beryllium (Be), or the like, and the n-type impurities can be silicon (Si), germanium, tin (Sn), or the like, but are not limited thereto. In the present disclosure, the second semiconductor layer 133 is defined as a p-type semiconductor layer doped with the p-type impurities but is not limited thereto.

The first electrode 134 is disposed on the first plane F1 of the first semiconductor layer 131. The first semiconductor layer 131 can be the semiconductor layer doped with n-type impurities, and the first electrode 134 can be a cathode. The first electrode 134 can be disposed on the top surface of the first semiconductor layer 131 exposed from the active layer 132 and the second semiconductor layer 133. The first electrode 134 can be formed of conductive materials, e.g., transparent conductive materials such as indium tin oxide (ITO) or indium zinc oxide (IZO), opaque conductive materials such as titanium (Ti), gold (Au), silver (Ag), copper (Cu), or an alloy thereof, or the like, but is not limited thereto.

A second electrode 135 is disposed on the second semiconductor layer 133. The second electrode 135 can be disposed on the top surface of the second semiconductor layer 133. In this situation, the second semiconductor layer 133 can be a semiconductor layer doped with p-type impurities, and the second electrode 135 can be an anode. The second electrode 135 can be formed of conductive materials, e.g., transparent conductive materials such as indium tin oxide (ITO) or indium zinc oxide (IZO), opaque conductive materials such as titanium (Ti), gold (Au), silver (Ag), copper (Cu), or an alloy thereof, or the like, but is not limited thereto.

FIGS. 3A and 3B are process diagrams illustrating a method of manufacturing a light emitting element according to an example embodiment of the present disclosure. FIG. 3A is a cross-sectional view illustrating the state after the MESA etching process. FIG. 3B is a cross-sectional view illustrating an isolation process for separating the light emitting element ED1 from a wafer WA.

Referring to FIG. 3A, the base layer 137, the first semiconductor layer 131, the active layer 132, and the second semiconductor layer 133 are disposed on the wafer WA.

Some areas of the active layer 132 and the second semiconductor layer 133 can be patterned through the MESA etching process. Here, the MESA etching process can refer to a process of defining a light emitting area of the plurality of light emitting elements ED1. The MESA etching process can refer to a process of leaving the active layer 132 and the second semiconductor layer 133 only in the area corresponding to a light emitting area of the plurality of light emitting elements ED1 on the wafer WA, and etching away the active layer 132 and the second semiconductor layer 133 from the area corresponding to a non-light emitting area of the plurality of light emitting elements ED1. In this situation, some areas of the first semiconductor layer 131 can also be etched in the MESA etching process. Accordingly, a thickness of the first semiconductor layer 131 disposed outside the active layer 132 and the second semiconductor layer 133 can be thinner than that of the first semiconductor layer 131 in the area overlapping the active layer 132 and the second semiconductor layer 133. In this way, a mesa shape or a mound shape is formed for each light emitting area.

Referring to FIG. 3A, a photoresist PR covers the active layer 132 and the second semiconductor layer 133 in order to perform an isolation process of separating the plurality of light emitting elements ED1 from the wafer WA. When the photoresist PR serves as a mask, the first semiconductor layer 131 and the base layer 137 can be etched in the areas that are not covered by the photoresist PR. In other words, the photoresist PR pattern protects areas that should be etched away.

When no process errors occur during the formation of the photoresist (e.g., when the photoresist PR pattern is perfectly aligned), the photoresist is disposed in the form of a dotted line as illustrated in FIG. 3A (e.g., the dotted line represents the ideal placement scenario), and the first semiconductor layer 131 and the base layer 137 can be etched normally. However, when a process error occurs during the formation of the photoresist (e.g., when the photoresist PR pattern is slightly misaligned or placed slightly off center), the photoresist PR can be disposed as illustrated in a solid line by being biased toward one side compared to the area illustrated in a dotted line (e.g., the solid line represents a scenario where the photoresist PR pattern is slightly misaligned or placed slightly off center). For example, since manufacturing can involve producing millions or billions of very small light emitting devices, misalignments regarding the placement of the photoresist PR pattern can occur during the manufacturing process due to slight errors. Accordingly, portions of the active layer 132 and the second semiconductor layer 133 can be exposed from the photoresist PR and uneven etching can occur. Meanwhile, portions of the active layer 132 and the second semiconductor layer 133 that are not covered by the photoresist PR can be affected by the isolation process. For example, one side of the light emitting device may undesirably etched more than the opposite side of the light emitting device, which can result in the light emitting device being uneven or having one side that has a different inclination angle than the other side, which can impair viewing quality and uniformity.

The side surfaces of the active layer 132 and the second semiconductor layer 133 that are not covered by the photoresist PR can be exposed to an etching process and etched together with the first semiconductor layer 131 and the base layer 137. In this situation, as illustrated in FIG. 3B, the inclination angle b of the second side surface S2 exposed to the outside by the photoresist PR can be larger than the inclination angle a of the second side surface S2 covered by the photoresist PR. For example, the stacked structure for the MESA shape can become undesirably lopsided or lean more toward one side.

When light generated from the light emitting element passes through the side surface of the MESA part of the light emitting element, a traveling direction of light on the side surface of the MESA part can change. Accordingly, the luminance distribution according to the viewing angle of the light emitting element can vary depending on the inclination angle of the area referred to as the MESA part of the light emitting element, that is, the side surfaces of the second semiconductor layer and the active layer.

The MESA part of the light emitting element can be formed through the MESA etching process, and an inclined surface of the MESA part of the light emitting element can be formed by the MESA etching process. Meanwhile, even after the MESA etching process, various processes of forming the light emitting element are performed. In this situation, the MESA part of the light emitting element can be exposed to various processes that are performed after the MESA etching process. For example, after the MESA etching process, the isolation process can be performed to separate the light emitting element by etching the wafer and the semiconductor layer disposed on the wafer. In this situation, the isolation process can refer to the process of separating the light emitting element from the wafer by etching the area corresponding to the outer periphery area of the light emitting element. Accordingly, the etching process performed in the isolation process is performed in areas excluding the MESA part. However, when a process deviation occurs, the MESA part can be exposed to the isolation process. For example, when the photoresist serves as the mask, one side of the MESA part can be covered by the photoresist due to the process error, but the other side of the MESA part can be exposed due to the difference in the area covered by the photoresist. Accordingly, the MESA part exposed due to the process deviation of the photoresist can be etched together with the wafer and the semiconductor layer disposed on the wafer. In this situation, the inclination angle of the inclined surface of the MESA part exposed in the isolation process can be different from the inclination angle of the inclined surface of the MESA part covered by the photoresist, and the deviation can occur in the inclination angle of the inclined surface of the MESA part. For example, the stacked structure for the MESA shape for the light emitting device can become undesirably lopsided or lean more toward one side, which can impair the viewing angle from one side.

In particular, when the light emitting element is a micro light-emitting diode (micro LED), the deviation in the inclination angle of the inclined surface of the MESA part can occur even with micrometer-level tolerances. For example, when the width of the MESA part is wide, the MESA part can be disposed adjacent to the outer periphery area of the light emitting element. Accordingly, even with a small error, some areas of the MESA part can be exposed by the photoresist and become lopsided. Therefore, when the width of the MESA part increases, the possibility or risk that the MESA part is exposed to the etching process increases, and the deviation in the inclination angle of the side surface of the MESA part can become worse, which can impair image quality. Accordingly, when the width of the MESA part increases, the deviation occurs in the inclination angle of the inclined surface of the MESA part of the light emitting element, so the possibility of color differences can increase depending on the viewing angle and a mura effect may be present or become visible to viewers depending on the viewing angle.

Accordingly, in the light emitting element ED1 according to the example embodiment of the present disclosure, the active layer 132 includes the plurality of first parts P1 and the second part P2 having a width smaller than the plurality of first parts P1. Accordingly, the plurality of first parts P1 can be disposed adjacent to the outer periphery area of the light emitting element ED1, but the second part P2 can be disposed more adjacent to the center of the light emitting element ED1 than the plurality of first parts P1. Accordingly, the second part P2 can be less affected by the manufacturing process of the light emitting element ED1, and in particular, the outer periphery area of the light emitting element ED1 can be less affected by the process deviation. In other words, the opposite sides of the narrower second parts P2 can be reliably protected during the manufacturing processes, in order to produce a more uniform light emitting device. For example, even if the process error occurs in the isolation process of separating the plurality of light emitting elements ED1 from the wafer WA, the second part P2 having a narrow width can still be covered by the photoresist PR. Accordingly, even if the deviation occurs in the inclination angle of the inclined surfaces of the plurality of first parts P1 in the manufacturing process of the light emitting element ED1, the inclination angle of the MESA part in the second part P2, that is, the inclination angle of the second side surface S2 can be uniformly formed, so the deviation in the viewing angle of the light emitting element ED1 can be reduced.

In addition, the light emitting element ED1 according to the example embodiment of the present disclosure includes the plurality of first parts P1 having a wider width than the second part P2. Accordingly, the light emitting area of the light emitting element ED1 in the first part P1 can increase, and the second part P2 and the first part P1 can be alternately disposed to improve the color difference according to the viewing angle of the light emitting element ED1. In other words, the total light emitting area of the light emitting device can be made larger via the first parts P1 to improve the overall brightness, while the narrower second parts P2 can be provided in order to ensure a wide viewing angle and a more uniform image that is free of mura issues or blemish defects.

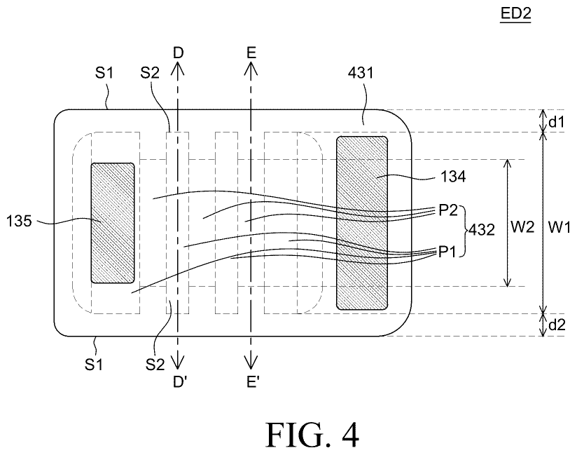

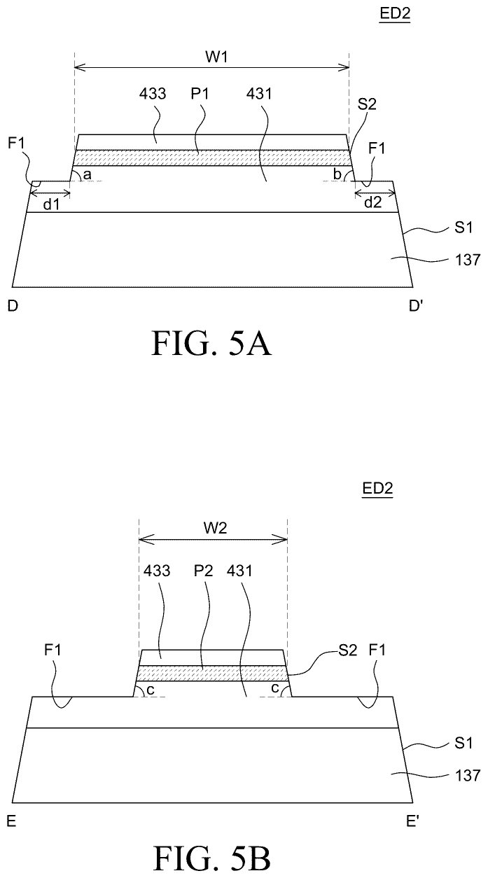

FIG. 4 is a schematic plan view of a light emitting element according to another example embodiment of the present disclosure. FIGS. 5A and 5B are cross-sectional views of a light emitting element according to another example embodiment of the present disclosure. A light emitting element ED2 of FIGS. 4 to 5B is different than the light emitting element ED1 of FIGS. 1 to 3B only in a first semiconductor layer 431, an active layer 432, and a second semiconductor layer 433 (e.g., when the MESA part is even centered). However, other components are substantially the same, so redundant description thereof will be omitted. In FIG. 4, for convenience of illustration, only the first semiconductor layer 431, the active layer 432, the first electrode 134, and the second electrode 135 of the light emitting element ED2 are illustrated. FIG. 5A is a cross-sectional view taken along line D-D′ of FIG. 4, and FIG. 5B is a cross-sectional view taken along line E-E′ of FIG. 4.

Referring to FIGS. 4 to 5B, the light emitting element ED2 includes the first plane F1 of the light emitting element ED2 protruding to the outside of the second semiconductor layer 433 and the active layer 432, the first side surface S1 extending downward from the first plane F1, and the second side surface S2 extending from the first plane F1 and extending upward. The first plane F1 of the light emitting element ED2 can be composed of a top surface of the first semiconductor layer 431, the first side surface S1 can be composed of a side surface of the first semiconductor layer 431, and the second side surface S2 can be composed of the side surface of the first semiconductor layer 431, the side surface of the active layer 432, and a side surface of the second semiconductor layer 433.

The first semiconductor layer 431, the active layer 432, and the second semiconductor layer 433 can be disposed above the base layer 137, and the active layer 432 includes the plurality of first parts P1 having the first width W1 in the width direction and the second parts P2 disposed between the plurality of first parts P1 and having the second width W2 smaller than the first width W1 in the width direction (e.g., W2<W1).

Meanwhile, the light emitting element ED2 illustrated in FIGS. 4 to 5B can be the light emitting element ED2 manufactured under conditions where no process error occurs during the manufacturing process, or the process deviation is substantially insignificant. For example, when the MESA part is designed to be disposed at the center of the width direction of the light emitting element ED2, as illustrated in FIG. 4, the active layer 432 can be disposed at the center of the width direction of the light emitting element ED2. That is, in this situation, as illustrated in FIG. 5A, the distance d1 between the second side surface S2 disposed toward a D side and the first side surface S1 in the first part P1 can be the same as or substantially equal to the distance d2 between the second side surface S2 disposed toward a D′ side and the first side surface S1 in the first part P1 (e.g., d1=d2). In other words, the MESA part can be uniformly centered.

Meanwhile, the distance between the second side surface S2 and the first side surface S1 in the first part P1 can refer to the shortest distance between the first side surface S1 and the second side surface S2 disposed on the light emitting element ED2. Accordingly, the distance d1 between the second side surface S2 disposed on the D side and the first side surface S1 in the first part P1, which is the shortest distance between the first side surface S1 and the second side surface S2 on one side in the width direction, can be the same as the distance d2 between the second side surface S2 disposed on the D′ side and the first side surface S1 in the first part P1, which is the shortest distance between the first side surface S1 and the second side surface S2 on the other side.

Meanwhile, the inclination angle between the second side surface S2 and the first plane F1 can be constant. That is, in FIG. 5A, the inclination angle a of the second side surface S2 disposed on the D side in the first part P1 can be the same as or substantially equal to the inclination angle b of the second side surface S2 disposed on the D′ side (e.g., inclination angle a=inclination angle b), and in FIG. 5B, can be the same as or substantially equal to the inclination angle c of the second side surface S2 disposed on an E side and the inclination angle c of the second side surface S2 disposed on an E′ side in the second part P2 (e.g., inclination angle c on one side=inclination angle c on the opposite side).

In the light emitting element ED2 according to another example embodiment of the present disclosure, the active layer 632 includes the plurality of first parts P1 and the second part P2 having a width smaller than the plurality of first parts P1. Accordingly, the second part P2 can be less affected by the deviation in the manufacturing process of the light emitting element ED2. Therefore, the inclination angle of the MESA part in the second part P2, that is, the inclination angle of the second side surface S2, can be formed uniformly. Thereby the deviation in the viewing angle of the light emitting element ED2 can be reduced.

In addition, the light emitting element ED2 according to another example embodiment of the present disclosure includes the plurality of first parts P1 having a wider width than the second part P2 (e.g., W1>W2). Accordingly, the light emitting area of the light emitting element ED2 in the first part P1 can increase, and the second part P2 and the first part P1 can be alternately disposed to improve the color difference according to the viewing angle of the light emitting element ED2.

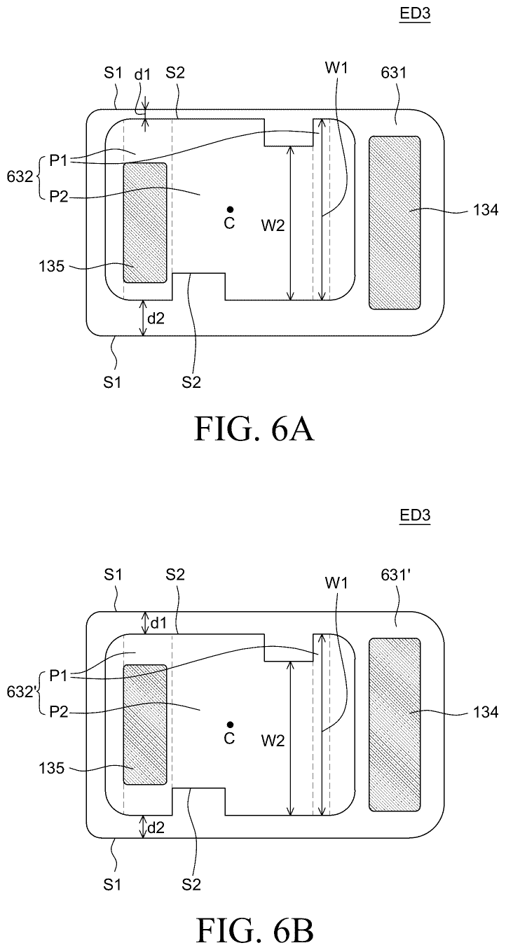

FIGS. 6A and 6B are schematic plan views of a light emitting element according to still another example embodiment of the present disclosure. A light emitting element ED3 of FIGS. 6A to 6B is different from the light emitting element ED1 of FIGS. 1 to 3B only in first semiconductor layers 631 and 631′, active layers 632 and 632′, and a second semiconductor layer. However, other components are substantially the same, so redundant description thereof will be omitted. FIG. 6A illustrates the light emitting element ED3 when the manufacturing process error occurs (e.g., the MESA shape is shifted slightly more toward the upper side in the drawing), and FIG. 6B illustrates the light emitting element ED3 manufactured under conditions where no process error occurs, or the process deviation is substantially insignificant (e.g., the MESA shape is uniformly centered). In FIGS. 6A and 6B, for convenience of illustration, only the first semiconductor layers 631 and 631′, the active layers 632 and 632′, the first electrode 134, and the second electrode 135 of the light emitting element ED3 are illustrated.

Referring to FIG. 6A, the light emitting element ED3 includes the first semiconductor layer 631, the active layer 632, the second semiconductor layer, the first electrode 134, and the second electrode 135. Referring to FIG. 6B, the light emitting element ED3 includes the first semiconductor layer 631′, the active layer 632′, the second semiconductor layer, the first electrode 134, and the second electrode 135.

The light emitting element ED3 can include the first plane F1 protruding to the outside of the second semiconductor layer and the active layers 632 and 632′. Referring to FIGS. 6A and 6B, the light emitting element ED3 includes the first side surface S1 extending downward from the first plane F1 and the second side surface S2 extending from the first plane F1 and extending upward. The first side surface S1 can be composed of the side surfaces of the first semiconductor layers 631 and 631′, and the second side surface S2 can be composed of the side surfaces of the first semiconductor layers 631 and 631′, the side surfaces of the active layers 632 and 632′, and the side surface of the second semiconductor layer.

Referring to FIGS. 6A and 6B, the first semiconductor layers 631 and 631′, the active layers 632 and 632′, and the second semiconductor layer can be disposed above the base layer 137, and the active layers 632 and 632′ include the plurality of first parts P1 having the first width W1 in the width direction and the second part P2 disposed between the plurality of first parts P1 and having the second width W2 smaller than the first width W1 in the width direction (e.g., W1>W2).

The second part P2 can have a point symmetry shape based on centers C of the active layers 632 and 632′. For example, the second part P2 can include a plurality of concave parts that are concavely formed toward the center of the light emitting element ED3. The plurality of concave parts faces each other in the width direction and can be disposed in a point symmetry shape. For example, referring to FIGS. 6A and 6B, one concave part is disposed adjacent to the first electrode 134 on one side, and the other concave part is disposed adjacent to the second electrode 135 on the other side opposite to one side (e.g., two concave parts disposed at opposite corners). For example, the second part P2 can have a shape that appears to have notches cut out or removed at opposite sides of opposite ends (e.g., a type of zig-zag shape or notches at opposite corners). The second part P2 can have a shape that has point symmetry with respect to central point c.

In this situation, in the area disposed outside the concave part, the side surface of the second part P2 can be disposed on the same plane as the side surface of the first part P1. For example, in the area adjacent to the first electrode 134 and the second electrode 135 of the light emitting element ED3, the side surface of the second part P2 can be disposed on the same plane as the side surface of the first part P1. Therefore, the second side surface S2 of the second part P2 disposed on one side of the light emitting element ED3 can be disposed on the same plane as the second side surface S2 of one of the plurality of first parts P1 disposed on both sides of the second part S2, and the second side surface S2 of the second part P2 disposed on the other side can be disposed on the same plane as the second side surface S2 of the other of the plurality of first parts P1 disposed on both sides of the second part P2.

Meanwhile, referring to FIG. 6A, the active layer 632 can be disposed to be biased in one direction with respect to the center of the light emitting element ED3. In this situation, as illustrated in FIG. 6A, the distance d1 between the second side surface S2 disposed on one side and the first side surface S1 in the first part P1 can be smaller than the distance d2 between the second side surface S2 disposed on the other side and the first side surface S1 in the first part P1 (e.g., d1<d2 in FIG. 6A because the MESA shape is slightly off center or slightly shifted).

In this situation, the inclination angle of the second side surface S2 of the first part P1 on one side can be larger than that of the second side surface S2 of the first part P1 on the other side, while the inclination angle of the second side surface S2 of the second part P2 on one side can be the same as that of the second side surface S2 of the second part P2 on the other side.

Referring to FIG. 6B, the active layer 632′ can be disposed at the center of the light emitting element ED3 in the width direction. That is, in this situation, as illustrated in FIG. 6B, the distance d1 between the second side surface S2 disposed on one side and the first side surface S1 in the first part P1 can be the same as the distance d2 between the second side surface S2 disposed on the other side and the first side surface S1 in the first part P1 (e.g., d1=d2 in FIG. 6B because the MESA shape is uniformly centered).

In addition, the inclination angles of the plurality of second side surfaces S2 disposed on the light emitting element ED3 can be constant and a wide viewing angle can be equally provided on both sides. The inclination angles of the second side surfaces S2 of the first part P1 can all be the same and can also be the same as the inclination angle of the second side surface S2 of the second part P2.

In the light emitting element ED3 according to still another example embodiment of the present disclosure, the active layers 632 and 632′ include the plurality of first parts P1 and the second part P2 having a width smaller than the plurality of first parts P1. Accordingly, the second part P2 can be less affected by the deviation in the manufacturing process of the light emitting element ED3. In other words, the protection of the second part P2 can be better guaranteed during the etching process since it has a narrower width and is more easily covered by a photoresist pattern. Therefore, the inclination angle of the MESA part in the second part P2, that is, the inclination angle of the second side surface S2, can be formed uniformly. Thereby any deviation in the viewing angle of the light emitting element ED3 can be reduced or prevented (e.g., a wide viewing angle can be provided to a user when viewing from a left side or when viewing from a right side, or in up/down directions, etc.).

In addition, the light emitting element ED3 according to still another example embodiment of the present disclosure includes the plurality of first parts P1 having a wider width than the second part P2. Accordingly, the light emitting area of the light emitting element ED3 in the first part P1 can increase and the second part P2 and the first part P1 can be alternately disposed to improve the color difference according to the viewing angle of the light emitting element ED3.

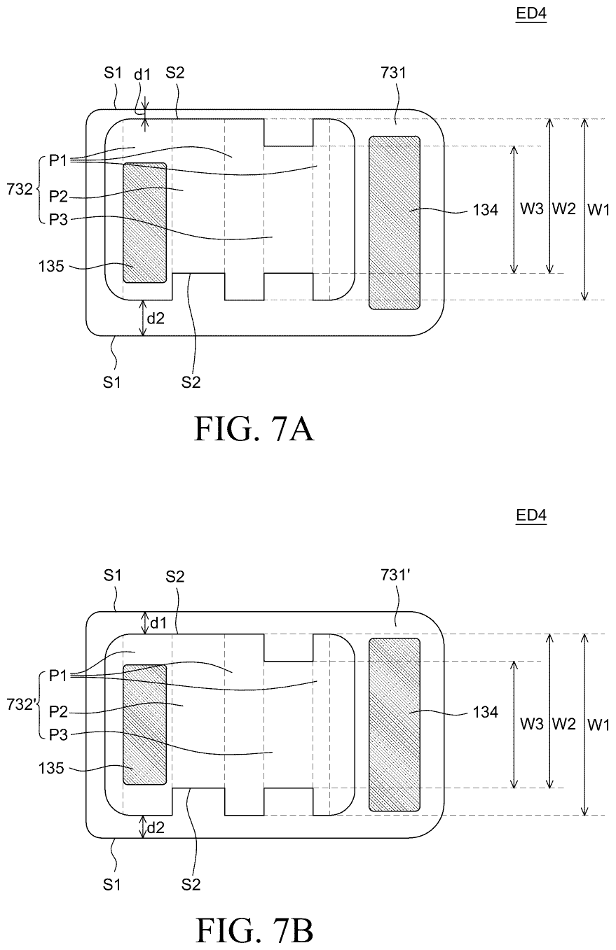

FIGS. 7A and 7B are schematic plan views of a light emitting element according to still another example embodiment of the present disclosure. A light emitting element ED4 of FIGS. 7A to 7B is different from the light emitting element ED1 of FIGS. 1 to 3B only in first semiconductor layers 731 and 731′, active layers 732 and 732′, and a second semiconductor layer. However, other components are substantially the same, so redundant description thereof will be omitted. FIG. 7A illustrates the light emitting element ED4 when the manufacturing process error occurs (e.g., the MESA shape is slight shifted toward one side), and FIG. 7B illustrates the light emitting element ED4 manufactured under conditions where no process error occurs, or the process deviation is substantially insignificant (e.g., the MESA shape is uniformly centered). In FIGS. 7A and 7B, for convenience of illustration, only the first semiconductor layers 731 and 731′, the active layers 732 and 732′, the first electrode 134, and the second electrode 135 of the light emitting element ED4 are illustrated.

Referring to FIG. 7A, the light emitting element ED4 includes the first semiconductor layer 731, the active layer 732, the second semiconductor layer, the first electrode 134, and the second electrode 135. Referring to FIG. 7B, the light emitting element ED4 includes the first semiconductor layer 731′, the active layer 732′, the second semiconductor layer, the first electrode 134, and the second electrode 135.

The light emitting element ED4 can include the first plane F1 protruding to the outside of the second semiconductor layer and the active layers 732 and 732′. Referring to FIGS. 7A and 7B, the light emitting element ED4 includes the first side surface S1 extending downward from the first plane F1 and the second side surface S2 extending from the first plane F1 and extending upward. The first side surface S1 can be composed of the side surfaces of the first semiconductor layers 731 and 731′, and the second side surface S2 can be composed of the side surfaces of the first semiconductor layers 731 and 731′, the side surfaces of the active layers 732 and 732′, and the side surface of the second semiconductor layer.

The first semiconductor layers 731 and 731′, the active layers 732 and 732′, and the second semiconductor layer can be disposed above the base layer 137, the active layers 732 and 732′ can include the plurality of first parts P1 having the first width W1 in the width direction, the second part P2 disposed between the plurality of first parts P1 and having the second width W2 smaller than the first width W1 in the width direction, and a third part P3 disposed between the plurality of first parts P1 and having a third width W3 smaller than the second width W2 in the width direction (e.g., W1>W2>W3).

In this situation, as illustrated in FIGS. 7A and 7B, the third part P3 can be disposed adjacent to the first electrode 134 of the first electrode 134 and the second electrode 135, but is not limited thereto, and can be disposed adjacent to the second electrode 135 or the center of the light emitting element ED4. In addition, in FIGS. 7A and 7B, the second part P2 and the third part P3 are illustrated to be alternately disposed between the plurality of first parts P1, but is not limited thereto, and the second part P2 and the third part P3 can be disposed continuously.

Meanwhile, referring to FIG. 7A, the active layer 732 can be disposed to be biased in one direction with respect to the center of the light emitting element ED4. In this situation, as illustrated in FIG. 7A, the distance d1 between the second side surface S2 disposed on one side and the first side surface S1 in the first part P1 can be smaller than the distance d2 between the second side surface S2 disposed on the other side and the first side surface S1 in the first part P1.

In this situation, the inclination angle of the second side surface S2 of the first part P1 on one side can be larger than that of the second side surface S2 of the first part P1 on the other side, while the inclination angle of the second side surface S2 of the second part P2 on one side can be the same as that of the second side surface S2 of the second part P2 on the other side.

Referring to FIG. 7B, the active layer 732′ can be disposed at the center of the light emitting element ED4 in the width direction. That is, in this situation, as illustrated in FIGS. 7A and 7B, the distance d1 between the second side surface S2 disposed on one side and the first side surface S1 in the first part P1 can be the same as the distance d2 between the second side surface S2 disposed on the other side and the first side surface S1 in the first part P1.

In addition, the inclination angles of the plurality of second side surfaces S2 disposed on the light emitting element ED4 can be constant. The inclination angles of the second side surfaces S2 of the first part P1 can all be the same and can also be the same as the inclination angle of the second side surface S2 of the second part P2.

In the light emitting element ED4 according to still another example embodiment of the present disclosure, the active layers 732 and 732′ include the plurality of first parts P1 and the second part P2 having a width smaller than the plurality of first parts P1. Accordingly, the second part P2 can be less affected by the deviation in the manufacturing process of the light emitting element ED4, and the third part P3 can be even better protected. Therefore, the inclination angle of the MESA part in the second part P2, that is, the inclination angle of the second side surface S2, can be formed uniformly. Thereby the deviation in the viewing angle of the light emitting element ED4 can be reduced.

The light emitting element ED4 according to still another embodiment of the present disclosure includes the third part P3 in which the active layers 732 and 732′ have a smaller width than the second part P2. Accordingly, the third part P3 can be less affected by the deviation in the manufacturing process of the light emitting element ED4. Therefore, the inclination angle of the MESA part in the third part P3, that is, the inclination angle of the second side surface S2, can be formed uniformly. Thereby the deviation in the viewing angle of the light emitting element ED4 can be reduced.

In addition, the light emitting element ED4 according to still another example embodiment of the present disclosure includes the plurality of first parts P1 with a wider width than the second part P2 and the third part P3 (e.g., W1>W2>W3). Accordingly, the light emitting area of the light emitting element ED4 in the first part P1 can increase, and the second part P2 and the third part P3, and the first part P1 can be alternately disposed to improve the color difference according to the viewing angle of the light emitting element ED4.

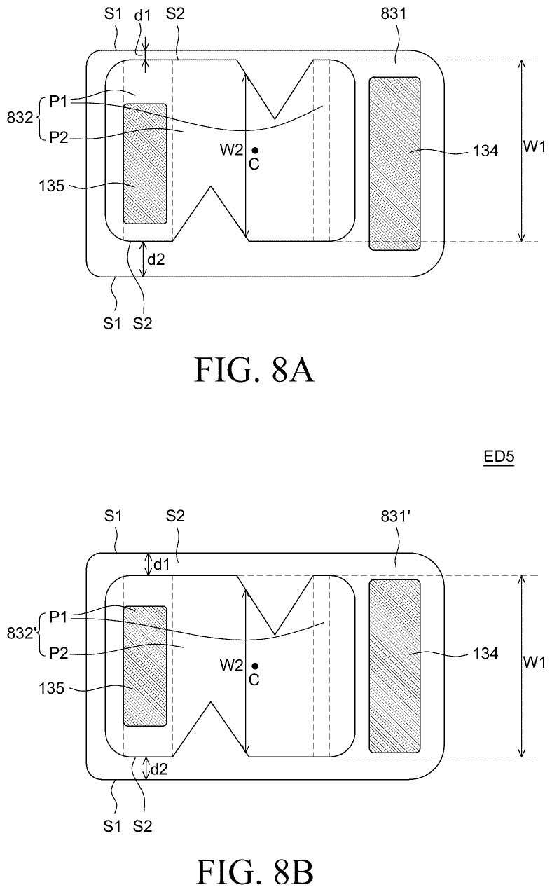

FIGS. 8A and 8B are schematic plan views of a light emitting element according to still another example embodiment of the present disclosure. A light emitting element ED5 of FIGS. 8A to 8B is different from the light emitting element ED3 of FIGS. 6A to 6B only in first semiconductor layers 831 and 831′, active layers 832 and 832′, and a second semiconductor layer (e.g., the active layer can have a “Z” shape or a zigzag shape in a plan view). However, other components are substantially the same, so redundant description thereof will be omitted. FIG. 8A illustrates the light emitting element ED5 when the manufacturing process error occurs (e.g., the MESA shape is slightly shifted), and FIG. 8B illustrates the light emitting element ED5 manufactured under conditions where no process error occurs, or the process deviation is substantially insignificant (e.g., the MESA shape is centered). In FIGS. 8A and 8B, for convenience of illustration, only the first semiconductor layers 831 and 831′, the active layers 832 and 832′, the first electrode 134, and the second electrode 135 of the light emitting element ED5 are illustrated.

Referring to FIG. 8A, the light emitting element ED5 includes the first semiconductor layer 831, the active layer 832, the second semiconductor layer, the first electrode 134, and the second electrode 135. Referring to FIG. 8B, the light emitting element ED5 includes the first semiconductor layer 831′, the active layer 832′, the second semiconductor layer, the first electrode 134, and the second electrode 135.

The light emitting element ED5 can include the first plane F1 protruding to the outside of the second semiconductor layer and the active layers 832 and 832′. Referring to FIGS. 8A and 8B, the light emitting element ED5 includes the first side surface S1 extending downward from the first plane F1 and the second side surface S2 extending from the first plane F1 and extending upward. The first side surface S1 can be composed of the side surfaces of the first semiconductor layers 831 and 831′, and the second side surface S2 can be composed of the side surfaces of the first semiconductor layers 831 and 831′, the side surfaces of the active layers 832 and 832′, and the side surface of the second semiconductor layer. The first semiconductor layers 831 and 831′, the active layers 832 and 832′, and the second semiconductor layer can be disposed above the base layer 137, and the active layers 832 and 832′ include the plurality of first parts P1 having the first width W1 in the width direction and the second part P2 disposed between the plurality of first parts P1 and having the second width W2 smaller than the first width W1 in the width direction (e.g., W1>W2).

The second part P2 can include the plurality of concave parts that is concavely formed toward the center of the light emitting element ED5. The plurality of concave parts of the second part P2 can be disposed in the point symmetry shape with respect to the center C of the second part P2. In this situation, the plurality of concave parts can be disposed so that the width of the second part P2 can gradually change. For example, as illustrated in FIGS. 8A and 8B, the planar shape of the plurality of concave parts of the second part P2 can be triangular. For example, the active layer can have a “Z” shape or a zigzag shape in a plan view, but embodiments are not limited thereto. The active layer can have a rounded or curved shape, e.g., an “S” shape. Accordingly, the width of the second part P2 can gradually change in the portion where the plurality of concave parts is disposed and can gradually change in the longitudinal direction.

Meanwhile, referring to FIG. 8A, the active layer 832 can be disposed to be biased in one direction with respect to the center of the light emitting element ED5. In this situation, as illustrated in FIG. 8A, the distance d1 between the second side surface S2 disposed on one side and the first side surface S1 in the first part P1 can be smaller than the distance d2 between the second side surface S2 disposed on the other side and the first side surface S1 in the first part P1.

In this situation, the inclination angle of the second side surface S2 of the first part P1 on one side can be larger than that of the second side surface S2 of the first part P1 on the other side, while the inclination angle of the second side surface S2 of the second part P2 on one side can be the same as that of the second side surface S2 of the second part P2 on the other side.

Referring to FIG. 8B, the active layer 832′ can be disposed at the center of the light emitting element ED5 in the width direction. That is, in this situation, as illustrated in FIGS. 8A and 8B, the distance d1 between the second side surface S2 disposed on one side and the first side surface S1 in the first part P1 can be the same as the distance d2 between the second side surface S2 disposed on the other side and the first side surface S1 in the first part P1.

In addition, the inclination angles of the plurality of second side surfaces S2 disposed on the light emitting element ED5 can be constant. The inclination angles of the second side surfaces S2 of the first part P1 can all be the same and can also be the same as the inclination angle of the second side surface S2 of the second part P2 and a wide viewing angle can be uniformly provided from different sides.

In the light emitting element ED5 according to still another example embodiment of the present disclosure, the active layers 832 and 832′ include the plurality of first parts P1 and the second part P2 having a width smaller than the plurality of first parts P1. Accordingly, the second part P2 can be less affected by the deviation in the manufacturing process of the light emitting element ED5. Therefore, the inclination angle of the MESA part in the second part P2, that is, the inclination angle of the second side surface S2, can be formed uniformly. Thereby any deviation in the viewing angle of the light emitting element ED5 can be reduced or prevented.

In addition, the light emitting element ED5 according to still another example embodiment of the present disclosure includes the plurality of first parts P1 having a wider width than the second part P2. Accordingly, the light emitting area of the light emitting element ED5 in the first part P1 can increase, and the second part P2 and the first part P1 can be alternately disposed to improve the color difference according to the viewing angle of the light emitting element ED5.

In addition, in the light emitting element ED5 according to still another example embodiment of the present disclosure, the width of the second part P2 can gradually change in the longitudinal direction. Accordingly, it is possible to suppress the size of the width from changing suddenly in a boundary area between the second part P2 and the first part P1, so the size of the deviation in the inclination angle of the second side surface S2 can decrease in the boundary area between the second part P2 and the first part P1.

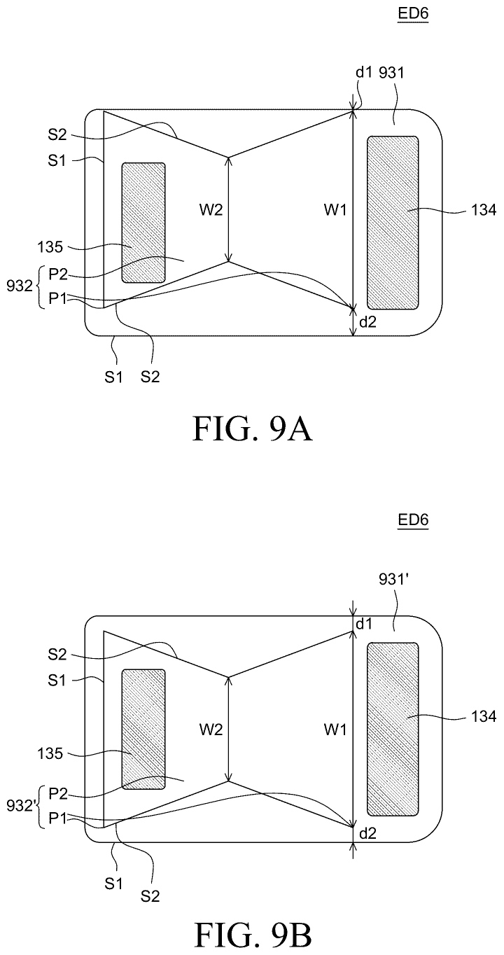

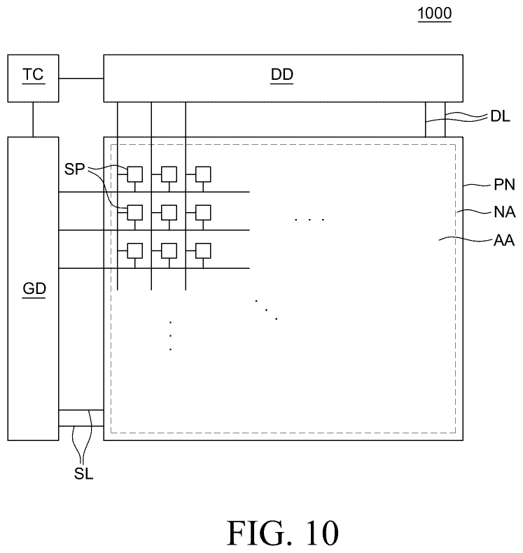

FIGS. 9A and 9B are schematic plan views of a light emitting element according to still another example embodiment of the present disclosure. A light emitting element ED6 of FIGS. 9A and 9B is different from the light emitting element ED1 of FIGS. 1 to 3B only in first semiconductor layers 931 and 931′, active layers 932 and 932′, and a second semiconductor layer (e.g., the active layer can have a symmetrical shape or a butterfly type of shape). However, other components are substantially the same, so redundant description thereof will be omitted. FIG. 9A illustrates the light emitting element ED6 when the manufacturing process error occurs (e.g., the MESA shale is slightly shifted due to an offset placement of a photoresist pattern), and FIG. 9B illustrates the light emitting element ED6 manufactured under conditions where no process error occurs, or the process deviation is substantially insignificant (e.g., the MESA shape is centered). In FIGS. 9A and 9B, for convenience of illustration, only the first semiconductor layers 931 and 931′, the active layers 932 and 932′, the first electrode 134, and the second electrode 135 of the light emitting element ED6 are illustrated.

Referring to FIG. 9A, the light emitting element ED6 includes the first semiconductor layer 931, the active layer 932, the second semiconductor layer, the first electrode 134, and the second electrode 135. Referring to FIG. 9, the light emitting element ED6 includes the first semiconductor layer 931′, the active layer 932′, the second semiconductor layer, the first electrode 134, and the second electrode 135.

The light emitting element ED6 can include the first plane F1 protruding to the outside of the second semiconductor layer and the active layers 932 and 932′. Referring to FIGS. 9A and 9B, the light emitting element ED6 includes the first side surface S1 extending downward from the first plane F1 and the second side surface S2 extending from the first plane F1 and extending upward. The first side surface S1 can be composed of the side surfaces of the first semiconductor layers 931 and 931′, and the second side surface S2 can be composed of the side surfaces of the first semiconductor layers 931 and 931′, the side surfaces of the active layers 932 and 932′, and the side surface of the second semiconductor layer.

The first semiconductor layers 931 and 931′, the active layers 932 and 932′, and the second semiconductor layer can be disposed above the base layer 137, and the active layers 932 and 832′ can include the plurality of first parts P1 having the first width W1 in the width direction and the second part P2 disposed between the plurality of first parts P1 and having the second width W2 smaller than the first width W1 in the width direction.

The width of the second part P2 can vary depending on a location. For example, the width of the second part P2 can gradually increase or decrease in the longitudinal direction. Referring to FIGS. 9A and 9B, the second width W2 of the second part P2 can be smallest at the center of the second part P2, and the second width W2 can increase as the distance from the center of the second part P2 increases. For example, the active layer can have a symmetrical “bow tie” type of shape. Also, according to an embodiment, the edges of the symmetrical shape do not have to be straight, e.g., they can be curved, bowed or wavy, etc.

Meanwhile, referring to FIG. 9A, the active layer 932 can be disposed to be biased in one direction with respect to the center of the light emitting element ED6. In this situation, as illustrated in FIG. 9A, the distance d1 between the second side surface S2 disposed on one side and the first side surface S1 in the first part P1 can be smaller than the distance d2 between the second side surface S2 disposed on the other side and the first side surface S1 in the first part P1.

In this situation, the inclination angle of the second side surface S2 of the first part P1 on one side can be larger than that of the second side surface S2 of the first part P1 on the other side, while the inclination angle of the second side surface S2 of the second part P2 on one side can be the same as that of the second side surface S2 of the second part P2 on the other side.

Referring to FIG. 9B, the active layer 932′ can be disposed at the center of the light emitting element ED6 in the width direction. That is, in this situation, as illustrated in FIG. 9B, the distance d1 between the second side surface S2 disposed on one side and the first side surface S1 in the first part P1 can be the same as the distance d2 between the second side surface S2 disposed on the other side and the first side surface S1 in the first part P1.

In addition, the inclination angles of the plurality of second side surfaces S2 disposed on the light emitting element ED6 can be constant. The inclination angles of the second side surfaces S2 of the first part P1 can all be the same and can also be the same as the inclination angle of the second side surface S2 of the second part P2.

In the light emitting element ED6 according to still another example embodiment of the present disclosure, the active layers 932 and 932′ include the plurality of first parts P1 and the second part P2 having a width smaller than the plurality of first parts P1. Accordingly, the second part P2 can be less affected by the deviation in the manufacturing process of the light emitting element ED6. Therefore, the inclination angle of the MESA part in the second part P2, that is, the inclination angle of the second side surface S2, can be formed uniformly. Thereby the deviation in the viewing angle of the light emitting element ED6 can be reduced.

In addition, the light emitting element ED6 according to still another example embodiment of the present disclosure includes the plurality of first parts P1 having a wider width than the second part P2. Accordingly, the light emitting area of the light emitting element ED6 in the first part P1 can increase, and the second part P2 and the first part P1 can be alternately disposed to improve the color difference according to the viewing angle of the light emitting element ED6.

In addition, in the light emitting element ED6 according to still another example embodiment of the present disclosure, the width of the second part P2 can gradually change in the longitudinal direction. For example, the width of the active layer can be the widest at the opposite ends and gradually decrease to a smallest width located at a center, in a plan view (e.g., a type of “bow tie” shape or “butterfly” shape). FIGS. 9A and 9B show the active layer having two opposing trapezoid shapes in the plan view, but embodiments are not limited thereto. For example, the active layer can have two opposing triangle shapes in the plan view, or a shape that is wider at the opposite ends and narrower at the center (e.g., a pinched oval shape, a pinched racetrack shape, a pinched stadium shape, etc.). Accordingly, it is possible to suppress the size of the width from changing suddenly in a boundary area between the second part P2 and the first part P1, so the size of the deviation in the inclination angle of the second side surface S2 can decrease in the boundary area between the second part P2 and the first part P1 and abrupt changes can be avoided.

FIG. 10 is a schematic configuration diagram of a display device according to an example embodiment of the present disclosure. For convenience of explanation, FIG. 10 illustrates only a display panel PN, a gate driver GD, a data driver DD, and a timing controller TC among various components of a display device 1000.

Referring to FIG. 10, the display device 1000 includes the display panel PN including a plurality of sub-pixels SP, the gate driver GD and the data driver DD that supply various signals to the display panel PN, and the timing controller TC that controls the gate driver GD and the data driver DD.

The gate driver GD supplies a plurality of scan signals to a plurality of scan lines SL according to a plurality of gate control signals provided from the timing controller TC. In FIG. 10, one gate driver GD is illustrated as being spaced apart from one side of the display panel PN, but the number and disposition of gate drivers GD are not limited thereto.

The data driver DD converts image data input from the timing controller TC into a data voltage using a reference gamma voltage according to a plurality of data control signals provided from the timing controller TC. The data driver DD can supply the converted data voltage to a plurality of data lines DL.

The timing controller TC sorts the image data input from the outside and supplies the sorted image data to the data driver DD. The timing controller TC can generate the gate control signal and the data control signal using a synchronization signal input from the outside, for example, a dot clock signal, a data enable signal, and a horizontal/vertical synchronization signal. The timing controller TC can control the gate driver GD and data driver DD by supplying the generated gate control signal and data control signal to the gate driver GD and data driver DD, respectively.

The display panel PN is configured to display images to users and includes a plurality of sub-pixels SP. In the display panel PN, a plurality of scan lines SL and a plurality of data lines DL intersect each other, and each of the plurality of sub-pixels SP is connected to the scan line SL and the data line DL. In addition, each of the plurality of sub-pixels SP can be connected to a high potential power line, a low potential power line, a reference line, etc.

A display area AA and a non-display area NA surrounding the display area AA can be defined in the display panel PN.

The display area AA is an area where an image is displayed on the display device 1000. A plurality of sub-pixels SP constituting a plurality of pixels and a circuit for driving the plurality of sub-pixels SP can be disposed in the display area AA. The plurality of sub-pixels SP is a minimum unit constituting the display area AA, and n sub-pixels SP can form one pixel. A light emitting element, a thin film transistor for driving the light emitting element, etc., can be disposed in each of the plurality of sub-pixels SP. A plurality of light emitting elements can be defined differently depending on a type of display panel PN. For example, when the display panel PN is an inorganic light emitting display panel, the light emitting element can be a light-emitting diode (LED) or a micro light-emitting diode (micro LED).

A plurality of lines that transmits various signals to the plurality of sub-pixels SP is disposed in the display area AA. For example, the plurality of lines can include the plurality of data lines DL that supplies a data voltage to each of the plurality of sub-pixels SP, and the plurality of scan lines SL that supplies a scan signal to each of the plurality of sub-pixels SP, etc. The plurality of scan lines SL can extend in one direction in the display area AA and be connected to the plurality of sub-pixels SP, and the plurality of data lines DL can extend a different direction from one direction in the display area AA and be connected to the plurality of sub-pixels SP. In addition, the low potential power line, the high potential power line, etc., can be further disposed in the display area AA, but are not limited thereto.

The non-display area NA is an area where an image is not displayed and can be defined as an area extending from the display area AA. Link lines and pad electrodes for transmitting signals to the sub-pixel SP of the display area AA, driver ICs such as gate driver Ics and data driver Ics, or the like can be disposed in the non-display area NA.

The non-display area NA can be located on a back surface of the display panel PN, that is, on a surface without the sub-pixel SP, or can be omitted, and is not limited to what is illustrated in the drawings.

Meanwhile, drivers such as the gate driver GD, the data driver DD, and the timing controller TC can be connected to the display panel PN in various manners. For example, the gate driver GD can be mounted in the non-display area NA using a gate in panel (GIP) manner and can be mounted between the plurality of sub-pixels SP in the display area (AA) using a gate in active area (GIA) manner. For example, the data driver DD and the timing controller TC can be formed on a separate flexible film and a printed circuit board PCB, and by bonding the flexible film and printed circuit board PCB to the pad electrode formed in the non-display area NA of the display panel PN, the data driver DD and the timing controller TC can be electrically connected to the display panel PN.

When the gate driver GD is mounted in the GIP manner and the data driver DD and the timing controller TC transmit signals to the display panel PN through the pad electrode in the non-display area NA, the area of the non-display area NA to dispose the gate driver GD and the pad electrode is required to be a certain level or more, so the bezel can increase.

In contrast, when the gate driver GD is mounted inside the display area AA using the GIA manner and the flexible film and the printed circuit board are bonded to the rear surface of the display panel PN by forming a side line for connecting a signal line on a front surface of the display panel PN to a pad electrode on a rear surface of the display panel PN, it is possible to reduce the non-display area NA in front of the display panel PN to a minimum. In other words, when the gate driver GD, the data driver DD, and the timing controller TC are connected to the display panel PN in the above manner, it can be possible to implement a zero bezel with substantially no bezel.

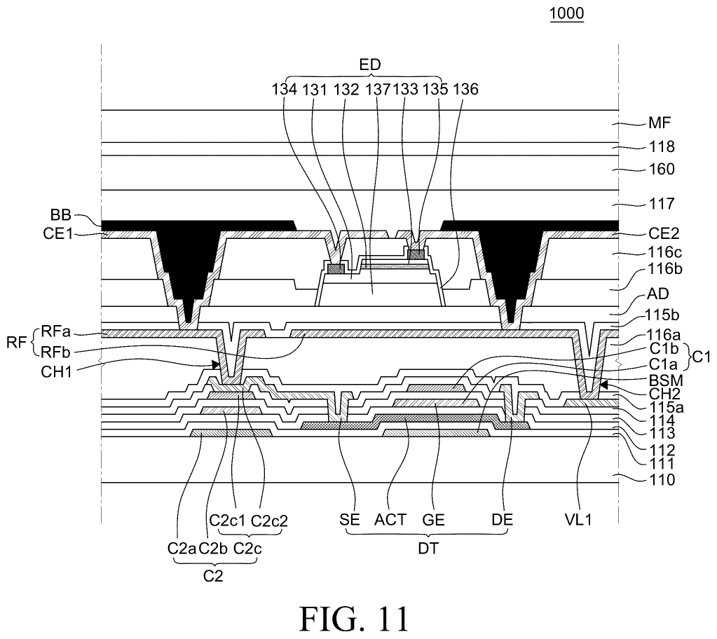

First, referring to FIG. 11, the display panel PN includes a first substrate 110. The first substrate 110 is a substrate that supports components disposed above the display device 1000 and can be an insulating substrate. A plurality of pixels can be formed on the first substrate 110 to display an image. For example, the first substrate 110 can be formed of glass, resin, or the like. In addition, the first substrate 110 can be formed of polymer or plastic. In some example embodiments, the first substrate 110 can be formed of a plastic material with flexibility.

The plurality of sub-pixels SP can be disposed on the first substrate 110 to form a plurality of rows and a plurality of columns. Each of the plurality of sub-pixels SP includes a light emitting element ED and a pixel circuit, and thus, can emit light independently.

The plurality of lines that transmits various signals to the plurality of sub-pixels SP is disposed in the first substrate 110. For example, the plurality of data lines DL, a plurality of high potential power lines VL1, and the plurality of low potential power lines extending in the column direction can be disposed on the first substrate 110. For example, a plurality of emission control signal lines, a plurality of auxiliary high potential power lines, a plurality of auxiliary low potential power lines, and a plurality of scan lines extending in the row direction can be disposed on the first substrate 110. In addition, the high potential power line VL1 extending in the column direction can be electrically connected to the auxiliary high potential power line extending in the row direction through a contact hole. In this situation, the emission control signal line can transmit an emission control signal to the pixel circuits of the plurality of sub-pixels SP, thereby controlling the emission timing of each of the plurality of sub-pixels SP.

The pixel circuits for driving the light emitting element ED are disposed in each of the plurality of sub-pixels SP on the first substrate 110. The pixel circuit can include a plurality of thin film transistors and a plurality of capacitors. In FIG. 11, for convenience of description, among the components of the pixel circuit, only a driving transistor DT, a first capacitor C1, and a second capacitor C2 are illustrated. However, the pixel circuit can further include a switching transistor, a sensing transistor, an emission control transistor, and the like, but is not limited thereto.

FIG. 11 is a cross-sectional view of a pixel area of a display device according to an example embodiment of the present disclosure.

Referring to FIG. 11, a light shielding layer BSM, the driving transistor DT, the first capacitor C1, the second capacitor C2, a reflection plate RF, the plurality of light emitting elements ED, a first connection electrode CE1, a second connection electrode CE2, a bank BB, a protective layer 117, an encapsulation layer 160, an adhesive part 118, an optical film MF, and an insulating layer including a plurality of inorganic insulating layers and a plurality of organic insulating layers can be disposed on the first substrate 110.

Among the insulating layers disposed on the first substrate 110, the plurality of inorganic insulating layers includes a buffer layer 111, a gate insulating layer 112, a first interlayer insulating layer 113, a second interlayer insulating layer 114, a first passivation layer 115a, and a second passivation layer 115b.

In addition, among the insulating layers disposed on the first substrate 110, the plurality of organic insulating layers can include a first planarization layer 116a, an adhesive layer AD, a second planarization layer 116b, and a third planarization layer 116c.

Referring to FIG. 11, the light shielding layer BSM is disposed on the first substrate 110. The light shielding layer BSM can minimize a leakage current by blocking light incident on active layers ACT of a plurality of transistors. For example, the light shielding layer BSM can be disposed below the active layer ACT of the driving transistor DT to block light incident on the active layer ACT. When light is irradiated to the active layer ACT, the leakage current can occur to decrease the reliability of the transistor. Therefore, the light shielding layer BSM blocking light can be disposed on the first substrate 110 to improve the reliability of the driving transistor DT. The light shielding layer BSM can be formed of opaque conductive materials, such as copper (Cu), aluminum (Al), molybdenum (Mo), nickel (Ni), titanium (Ti), chromium (Cr), or an alloy thereof, but is not limited thereto.

The buffer layer 111 is disposed on the light shielding layer BSM. The buffer layer 111 is the inorganic insulating layer that can reduce the penetration of moisture or impurities through the first substrate 110. The buffer layer 111 can be configured by, for example, a single layer or a double layer of silicon oxide (SiOx) or silicon nitride (SiNx) but is not limited thereto. However, the buffer layer 111 can be omitted depending on the type of first substrate 110 or the type of thin film transistor but is not limited thereto.

The driving transistor DT including the active layer ACT, a gate electrode GE, a source electrode SE, and a drain electrode DE is disposed on the buffer layer 111.

In addition, an additional buffer layer can be disposed between the first substrate 110 and the light shielding layer BSM. The additional buffer layer is an inorganic insulating layer that can reduce the penetration of moisture or impurities through the first substrate 110 in the same way as the buffer layer 111 described above and can be configured by a single layer of silicon oxide (SiOx) or silicon nitride (SiNx) or a double layer thereof but is not limited thereto.

First, the active layer ACT of the driving transistor DT is disposed on the buffer layer 111. The active layer ACT can be formed of a semiconductor material such as oxide semiconductor, amorphous silicon, or polysilicon, but is not limited thereto. Also, in addition to the driving transistor DT, other transistors, such as a switching transistor, a sensing transistor, and an emission control transistor, can be additionally disposed, and the active layers of these transistors can also be formed of semiconductor materials such as oxide semiconductor, amorphous silicon, or polysilicon, but the present disclosure is not limited thereto. In addition, the active layers of the transistors included in the pixel circuit, such as the driving transistor DT, the switching transistor, the sensing transistor, and the emission control transistor, can be formed of the same material or can be formed of different materials.

The gate insulating layer 112 is disposed on the active layer ACT. The gate insulating layer 112 is an inorganic insulating layer for electrically insulating the active layer ACT and the gate electrode GE and can be configured by a single layer of silicon oxide (SiOx) or silicon nitride (SiNx) or a double layer thereof but is not limited thereto.

The gate electrode GE is disposed on the gate insulating layer 112. The gate electrode GE can be formed of conductive materials, such as copper (Cu), aluminum (Al), molybdenum (Mo), nickel (Ni), titanium (Ti), chromium (Cr), or an alloy thereof, but is not limited thereto.

The first interlayer insulating layer 113 and the second interlayer insulating layer 114 are disposed on the gate electrode GE. Contact holes are formed in the first interlayer insulating layer 113 and the second interlayer insulating layer 114 to connect the source electrode SE and the drain electrode DE to the active layer ACT, respectively. The first interlayer insulating layer 113 and the second interlayer insulating layer 114 can be the inorganic insulating layer to protect lower components and can be configured by a single layer or a double layer of silicon oxide (SiOx) or silicon nitride (SiNx) but are not limited thereto.

The source electrode SE and the drain electrode DE, which are electrically connected to the active layer ACT, are disposed on the second interlayer insulating layer 114. The source electrode SE is connected to the second capacitor C2 and the first electrode 134 of the light emitting element ED, and the drain electrode DE is connected to other components of the pixel circuit. The source electrode SE and the drain electrode DE can be formed of a conductive material, such as copper (Cu), aluminum (Al), molybdenum (Mo), nickel (Ni), titanium (Ti), chromium (Cr), or an alloy thereof, but are not limited thereto.

The plurality of high potential power lines VL1 is disposed on the second interlayer insulating layer 114. The plurality of high potential power lines VL1 can transmit a high potential power voltage to the light emitting element ED of each of the plurality of sub-pixels SP. The plurality of high potential power lines VL1 can be formed of a conductive material, such as copper (Cu), aluminum (Al), molybdenum (Mo), nickel (Ni), titanium (Ti), chromium (Cr), or an alloy thereof, but is not limited thereto.

Next, the first capacitor C1 is disposed on the gate insulating layer 112. The first capacitor C1 includes a 1-1-th capacitor electrode C1a and a 1-2-th capacitor electrode C1b.

First, the 1-1-th capacitor electrode C1a is disposed on the gate insulating layer 112. The 1-1-th capacitor electrode C1a can be integrated with the gate electrode GE of the driving transistor DT.

The 1-2-th capacitor electrode C1b is disposed on the first interlayer insulating layer 113. The 1-2-th capacitor electrode C1b is disposed to overlap the 1-1-th capacitor electrode C1a with the first interlayer insulating layer 113 interposed therebetween.

Accordingly, the first capacitor C1 can be connected to the gate electrode GE of the driving transistor DT and can maintain the voltage of the gate electrode GE of the driving transistor DT for a certain period of time.

Next, the second capacitor C2 is disposed on the first substrate 110. The second capacitor C2 includes a 2-1-th capacitor electrode C2a, a 2-2-th capacitor electrode C2b, and a 2-3-th capacitor electrode C2c. The second capacitor C2 includes a 2-1-th capacitor electrode C2a as a lower capacitor electrode, a 2-2-th capacitor electrode C2b as an intermediate capacitor electrode, and a 2-3-th capacitor electrode C2c as an upper capacitor electrode.

The 2-1-th capacitor electrode C2a is disposed on the first substrate 110. The 2-1-th capacitor electrode C2a can be disposed on the same layer as the light shielding layer BSM and can be formed of the same material.

The 2-2-th capacitor electrode C2b is disposed on the buffer layer 111 and the gate insulating layer 112. The 2-2-th capacitor electrode C2b can be disposed on the same layer as the gate electrode GE and can be formed of the same material.

The 2-3-th capacitor electrode C2c is disposed on the first interlayer insulating layer 113. The 2-3-th capacitor electrode C2c can be composed of a first layer C2c1 and a second layer C2c2. The first layer C2c1 of the 2-3-th capacitor electrode C2c can be formed of the same material as the 1-2-th capacitor electrode C1b on the same layer. The first layer C2c1 can be disposed to overlap the 2-1-th capacitor electrode C2a and the 2-2-th capacitor electrode C2b with the first interlayer insulating layer 113 interposed therebetween.

The second layer C2c2 of the 2-3-th capacitor electrode C2c is disposed on the second interlayer insulating layer 114. The second layer C2c2 is a part extending from the source electrode SE of the driving transistor DT and can be connected to the first layer C2c1 through the contact hole in the second interlayer insulating layer 114.

Therefore, the second capacitor C2 is electrically connected between the source electrode SE of the driving transistor DT and the light emitting element ED, so the capacitance inherent in the light emitting element ED can increase and light with higher luminance can be emitted from the light emitting element ED.

A first passivation layer 115a is disposed on the driving transistor DT, the first capacitor C1, and the second capacitor C2. The first passivation layer 115a is an inorganic insulating layer to protect components below the first passivation layer 115a and can be formed of an inorganic material such as silicon oxide (SiOx) or silicon nitride (SiNx) but is not limited thereto.

The first planarization layer 116a is disposed on the first passivation layer 115a. The first planarization layer 116a can planarize an upper portion of the pixel circuit including the driving transistor DT. The first planarization layer 116a can be configured by a single layer or a double layer, and can be formed of, for example, a benzocyclobutene or acryl-based organic insulating layer.

Referring to FIG. 11, a plurality of reflection plates RF is disposed on the first planarization layer 116a. The reflection plate RF is configured to reflect light emitted from the plurality of light emitting elements ED to the upper portion of the first substrate 110 (e.g., in a direction toward a viewer's eyes) and can have a shape corresponding to each of the plurality of sub-pixels SP. One reflection plate RF can be disposed to cover most of the area of one sub-pixel SP. The reflection plate RF can reflect light emitted from the light emitting element ED and at the same time, can also be used as an electrode to electrically connect the light emitting element ED and the pixel circuit. Accordingly, the reflection plate RF can include various conductive layers in consideration of light reflection efficiency and resistance. For example, the reflection plate RF can be configured by the opaque conductive layer such as silver (Ag), aluminum (Al), molybdenum (Mo), titanium (Ti), or an alloy thereof, along with a transparent conductive layer such as indium tin oxide (ITO). However, the structure of the reflection plate RF is not limited thereto.

The reflection plate RF can include a plurality of first reflection plates RFa and a plurality of second reflection plates RFb disposed in each of the plurality of sub-pixels SP.

The plurality of first reflection plates RFa can reflect the light emitted from the light emitting element ED to the outside of the display device 1000. The plurality of first reflection plates RFa can be disposed in each driving transistor DT in each of the plurality of sub-pixels SP and can be electrically connected to the source electrode SE of the driving transistor DT and the second capacitor C2 through a first contact hole CH1.

The plurality of second reflection plates RFb can be disposed to overlap the light emitting element ED. The plurality of second reflection plates RFb can be disposed on each driving transistor DT in each of the plurality of sub-pixels SP and connected to the high potential power line VL1 through a second contact hole CH2. Accordingly, the plurality of second reflection plates RFb can reflect the light emitted from the light emitting element ED to the outside of the display device 1000 while supplying the high potential power voltage to the light emitting element ED.

Meanwhile, all of the plurality of light emitting elements ED can be separately connected to the high potential power line VL1 without the reflection plate RF but are not limited thereto.

Referring to FIG. 11, the second passivation layer 115b is disposed on the plurality of reflection plates RF. The second passivation layer 115b is the inorganic insulating layer to protect components below the second passivation layer 115b and can be configured by a single layer of silicon oxide (SiOx) or silicon nitride (SiNx) or a double layer thereof but is not limited thereto.

The adhesive layer AD is disposed on the second passivation layer 115b. The adhesive layer AD can be formed on the front surface of the first substrate 110 and fix the light emitting element ED disposed on the adhesive layer AD. The adhesive layer AD can be configured by an organic insulating layer. The adhesive layer AD can be formed of a photocurable adhesive material that can be cured by light. For example, the adhesive layer AD can be formed of an acrylic-based material containing a photoresist but is not limited thereto.

The plurality of light emitting elements ED is disposed in each of the plurality of sub-pixels SP on the adhesive layer AD. The light emitting element ED is an element that emits light by a current and can include a light emitting element emitting red light, a second light emitting element emitting green light, and a third light emitting element emitting blue light, and implement light of various colors, including white, by a combination thereof. For example, the light emitting element ED can be a light emitting diode (LED) or a micro LED but is not limited thereto.

The plurality of light emitting elements ED includes the first semiconductor layer 131, the active layer 132, the second semiconductor layer 133, the first electrode 134, and the second electrode 135. Hereinafter, the description will be made on the assumption that the plurality of light emitting elements ED has a lateral structure, but the type of the plurality of light emitting elements ED is not limited thereto. In addition, in FIG. 11, the plurality of light emitting elements ED is described as applying the light emitting elements ED described in FIGS. 1 to 3B, but is not limited thereto, and all the light emitting elements according to various example embodiments of the present disclosure described in FIGS. 4 to 9B can be applied. Since the plurality of light emitting elements ED has been described in detail with reference to FIGS. 1 to 3B, redundant description thereof will be omitted.

Next, an encapsulation film 136 surrounding the first semiconductor layer 131, the active layer 132, the second semiconductor layer 133, the first electrode 134, and the second electrode 135 is disposed. The encapsulation film 136 is formed of an insulating material and can protect the first semiconductor layer 131, the active layer 132, and the second semiconductor layer 133. The contact holes can be formed in the encapsulation film 136 to expose the first electrode 134 and the second electrode 135, so the first connection electrode CE1 and the second connection electrode CE2 can be electrically connected to the first electrode 134 and the second electrode 135.

Meanwhile, the encapsulation film 136 can surround only a portion of the light emitting element ED in consideration of the process margin. The encapsulation film 136 can cover all of the side surfaces of the second semiconductor layer 133 and the active layer 132 and can cover a portion of the side surface of the first semiconductor layer 131. For example, the encapsulation film 136 can cover the side surface of the light emitting element ED on which the first electrode 134 is disposed and expose the side surface of the light emitting element ED on which the second electrode 135 is disposed, but is not limited thereto.

In addition, a portion of the side surface of the first semiconductor layer 131 can be exposed from the encapsulation film 136. The light emitting element ED manufactured on the wafer can be separated from the wafer and transferred to the display panel PN. However, during the process of separating the light emitting element ED from the wafer, a portion of the encapsulation film 136 can be torn. For example, a portion of the encapsulation film 136 adjacent to the lower edge of the first semiconductor layer 131 of the light emitting element ED is torn off during the process of separating the light emitting element ED and the wafer, so a portion of the lower side surface of the first semiconductor layer 131 can be exposed to the outside. However, even if the lower portion of the light emitting element ED is exposed from the encapsulation film 136, the second planarization layer 116b and the third planarization layer 116c covering the side surface of the first semiconductor layer 131 can be formed and then the first connection electrode CE1 and the second connection electrode CE2 can be formed. Thereby the short circuit defects can be reduced.

Next, the second planarization layer 116b and the third planarization layer 116c are disposed on the adhesive layer AD and the light emitting element ED.

The second planarization layer 116b can overlap a portion of the side surface portion of the plurality of light emitting elements ED to fix and protect the plurality of light emitting elements ED. The second planarization layer 116b can be configured by a single layer or a double layer, and can be formed of, for example, a benzocyclobutene or acryl-based organic insulating layer. The second planarization layer 116b can be formed using a halftone mask. Accordingly, the second planarization layer 116b can be formed to have a step.

Specifically, in the second planarization layer 116b, the portion disposed relatively adjacent to the light emitting element ED can be formed to have a relatively thin thickness, and the portion disposed relatively far from the light emitting element ED can be formed to have a relatively thick thickness. A portion of the second planarization layer 116b disposed adjacent to the light emitting element ED can be disposed to surround the light emitting element ED and be in contact with the side surface of the light emitting element ED. Accordingly, in the process of separating the light emitting element ED from the wafer and transferring the light emitting element ED to the display panel PN, the portion where the encapsulation film 136 that protects the side surface of the first semiconductor layer 131 of the light emitting element ED is torn out can be covered with the second planarization layer 116b. As a result, it is possible to suppress the contact and short circuit defects between the first and second connection electrodes CE1 and CE2 and the first semiconductor layer 131 in the future.

The third planarization layer 116c can be formed to cover the second planarization layer 116b and the upper portion of the light emitting element ED and can be formed with the contact holes through which the first electrode 134 and the second electrode 135 of the light emitting element ED are exposed. The first electrode 134 and the second electrode 135 of the light emitting element ED can be exposed from the third planarization layer 116c, and the third planarization layer 116c can be partially disposed in the area between the first electrode 134 and the second electrode 135, thereby short circuit defects can be reduced. The second planarization layer 116b and the third planarization layer 116c can be configured by a single layer or a double layer, and can be formed of, for example, photoresist or an acryl-based organic insulating material.

Meanwhile, the third planarization layer 116c can cover the light emitting element ED and the area adjacent to the light emitting element ED. The third planarization layer 116c can be disposed in the area of the sub-pixel SP surrounded by the bank BB and can be disposed in an island shape. Accordingly, the bank BB can be disposed on a portion of the top surface of the second planarization layer 116b. For example, the bank BB can be disposed on the third planarization layer 116c to overlap with a portion of the third planarization layer 116c.

The first connection electrode CE1 and the second connection electrode CE2 are disposed on the third planarization layer 116c.

The first connection electrode CE1 is an electrode that electrically connects the first electrode 134 of the light emitting element ED and the driving transistor DT. The first connection electrode CE1 can be electrically connected to the first electrode 134 exposed from the third planarization layer 116c, and at the same time can be connected to the first reflection plate RFa through the contact holes formed in the third planarization layer 116c, the second planarization layer 116b, the adhesive layer AD, and the second passivation layer 115b. Accordingly, the first electrode 134 and the source electrode SE of the driving transistor DT can be electrically connected through the first connection electrode CE1 and the first reflection plate RFa.

The second connection electrode CE2 is an electrode that electrically connects the second electrode 135 of the light emitting element ED and the high potential power line VL1. The second connection electrode CE2 can be electrically connected to the second reflection plate RFb through the contact holes formed in the third planarization layer 116c, the second planarization layer 116b, the adhesive layer AD, and the second passivation layer 115b while being electrically connected to the second electrode 135 exposed from the third planarization layer 116c. Accordingly, the second electrode 135 and the high potential power line VL1 can be electrically connected through the second connection electrode CE2.

The first connection electrode CE1 and the second connection electrode CE2 can be formed of transparent conductive materials such as indium tin oxide (ITO) or indium zinc oxide (IZO) but are not limited thereto.

Meanwhile, in the drawings, the first electrode 134, the first connection electrode CE1, the reflection plate RF, and the first reflection plate RFa are illustrated as being electrically connected to the source electrode SE of the driving transistor DT, but the first electrode 134, the first connection electrode CE1, the reflection plate RF, and the first reflection plate RFa can be connected to the drain electrode DE of the driving transistor DT, but are not limited thereto.

Referring to FIG. 11, the bank BB is disposed on the first and second connection electrodes CE1 and CE2 and the second planarization layer 116b exposed from the third planarization layer 116c. The bank BB can be disposed at a certain distance to be spaced apart from the light emitting elements ED, and can overlap with at least a portion of the reflection plate RF. For example, the bank BB can cover a portion of the first and second connection electrodes CE1 and CE2 formed in the contact holes of the third planarization layer 116c and the second planarization layer 116b. In addition, the bank BB can be disposed on the second planarization layer 116b at a certain distance from the light emitting element ED, for example.

The bank BB can be formed of opaque materials to reduce or prevent color mixing between the plurality of sub-pixels SP, and formed of, for example, a black resin, which can improve image quality, but embodiments are not limited thereto.

Meanwhile, a thickness of a portion of the bank BB that is formed in the contact holes of the third planarization layer 116c and the second planarization layer 116b and covers a portion of the first connection electrode CE1 and the second connection electrode CE2 and a thickness of a portion that is disposed on the second planarization layer 116b can be different. Specifically, in the situation of a portion of the bank BB that covers a portion of the first and second connection electrodes CE1 and CE2 formed in the contact holes of the third planarization layer 116c and the second planarization layer 116b, the contact holes are formed from the second passivation layer 115b to the third planarization layer 116c, so the bank BB can be disposed below the light emitting element ED, that is, to a position lower than the light emitting element ED. Accordingly, the thickness of the portion of the bank BB that is formed in the contact holes of the third planarization layer 116c and the second planarization layer 116b and covers a portion of the first connection electrode CE1 and the second connection electrode CE2 can be thicker than a thickness of the portion of the band BB that is disposed on the second planarization layer 116b.

Meanwhile, the present disclosure is not limited thereto, and the bank BB is disposed outside the contact holes of the third planarization layer 116c and the second planarization layer 116b to cover portions of the first connection electrode CE1 and the second connection electrode CE2.

A protective layer 117 is disposed on the first connection electrode CE1, the second connection electrode CE2, and the bank BB. The protective layer 117 is a layer to protect components below the protective layer 117. The protective layer 117 can be configured by a single layer or a double layer, and can be formed of, for example, benzocyclobutene, light-transmissive epoxy, photoresist, or acryl-based organic material, but is not limited thereto.

The encapsulation layer 160 is disposed above the protective layer 117. The encapsulation layer 160 is a layer for minimizing moisture permeation from the outside of the display device 1000 and encapsulating the components surrounded by the encapsulation layer 160. The encapsulation layer 160 can be disposed to surround the front surface, side surface, and rear surface of the first substrate 110.

The encapsulation layer 160 can be formed of a material with low moisture permeability and high insulating properties. For example, the encapsulation layer 160 can be formed of a material containing parylene, but is not limited thereto.

Referring to FIG. 11, the optical film MF covering the upper portion of the encapsulation layer 160 is disposed in the entire upper area of the first substrate 110. The optical film MF can be disposed on a seal member 150 and the protective layer 117. The optical film MF can be a functional film that implements higher-quality images while protecting the display device 1000. For example, the optical film MF can include an anti-scattering film, an anti-glare film, an anti-reflecting film, a low-reflecting film, an OLED transmittance controllable film, a polarizer, etc., but is not limited thereto.

The adhesive part 118 can be disposed between the protective layer 117 and the optical film MF above the first substrate 110. The adhesive part 118 can be formed on the front surface of the first substrate 110 to bond the protective layer 117 and the optical film MF. The adhesive part 118 can be formed of a photocurable adhesive material that can be cured by light. For example, the adhesive part 118 can be formed of an acrylic-based material containing a photoresist but is not limited thereto.

Meanwhile, in the present disclosure, the adhesive part 118 and the optical film MF are defined as separate components, but are not limited thereto, and the optical film MF and the adhesive part 118 can be defined as one component.

The example embodiments of the present disclosure can also be described as follows:

According to an aspect of the present disclosure, there is provided a light emitting element. The light emitting element includes a first semiconductor layer, a first electrode and an active layer disposed on the first semiconductor layer to be spaced apart from each other, a second semiconductor layer on the active layer, and a second electrode on the second semiconductor layer, in which the active layer includes, a plurality of first parts having a first width in a width direction, and a second part disposed between the plurality of first parts and a second part having a second width smaller than the first width in the width direction.

Corner parts of the first semiconductor layer, the active layer, and the second semiconductor layer can have a round shape (e.g., rounded corners).

The first semiconductor layer can have a constant width in the width direction except for the corner part.

The light emitting element can further include a first plane on which the first electrode is disposed, a first side surface extending downward from the first plane, and a second side surface extending upward from the first plane. A distance between the first side surfaces facing in the width direction can be constant. A distance between the second side surfaces facing in the width direction in the plurality of first parts can be longer than a distance between the second side surfaces facing in the width direction in the second part.

At least a portion of the second side surface of the second part can be disposed inside the second side surface of the first part.

A shortest distance between the first side surface and the second side surface on one side and a shortest distance between the first side surface and the second side surface on the other side in the width direction can be the same.

An inclination angle of the second side surface can be constant.

A shortest distance between the first side surface and the second side surface on one side can be smaller than a shortest distance between the first side surface and the second side surface on the other side in the width direction.

An inclination angle of the second side surface of the first part on the one side can be larger than that of the second side surface of the first part on the other side.

An inclination angle of the second side surface of the second part on the one side can be the same as that of the second side surface of the second part on the other side.

The light emitting element can further include a substrate including a first area and a second area, in which the number of second parts is plural, and the plurality of first parts and the plurality of second parts can be alternately disposed.

The second part can have a point symmetry shape with respect to a center of the active layer.

The second side surface of the second part disposed on one side can be disposed on the same plane as the second side surface of one of the plurality of first parts disposed on both sides of the second part. The second side surface of the second part disposed on the other side can be disposed on the same plane as the second side surface of the other of the plurality of first parts disposed on the both sides of the second part.

The active layer can be disposed between the plurality of first parts. The active layer can further include a third part having a third width smaller than the second width in the width direction.

The second width can increase as a distance from a center of the second part increases.

The light emitting element can further include an encapsulation film covering a top surface and the side surface of the light emitting element. The encapsulation film can cover all side surfaces of the second semiconductor layer and the active layer and cover a portion of a side surface of the first semiconductor layer.

According to another aspect of the present disclosure, there is provided a display device. The display device includes a substrate, and a plurality of light emitting elements disposed on the substrate. Each of the plurality of light emitting elements includes a first electrode and an active layer disposed on the first semiconductor layer, a second semiconductor layer on the active layer, and a second electrode disposed on the second semiconductor layer to be spaced apart from the first electrode along a longitudinal direction. The active layer includes a first part having a first width, and a second part having the same width as the first part and a second width smaller than the first width.

The light emitting element can include a first side surface disposed below the first electrode, and a second side surface spaced apart from the first side surface and disposed above the first electrode. The second side surface of the first part can include at least one surface having a different inclination angle, and the second side surface of the second part can be formed of a surface having the same inclination angle.

The active layer can be disposed to be biased toward one side with respect to a width direction of the light emitting element.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A light emitting element, comprising:
a first semiconductor layer;
a first electrode and an active layer disposed on the first semiconductor layer, the first electrode being spaced apart from the active layer;
a second semiconductor layer disposed on the active layer; and
a second electrode disposed on the second semiconductor layer,
wherein the active layer includes:
a plurality of first parts having a first width in a width direction; and
a second part disposed between at least two of the plurality of first parts, the second part having a second width smaller than the first width in the width direction.

2. The light emitting element of claim 1, wherein the first semiconductor layer, the active layer, and the second semiconductor layer have rounded corners,
wherein the first semiconductor layer has a constant width in the width direction except for the rounded corners of the first semiconductor layer.

3. The light emitting element of claim 2, further comprising:
a first plane on the first semiconductor layer, the first electrode being disposed on the first plane of the first semiconductor layer;
first side surfaces extending in a downward direction from the first plane; and
second side surfaces extending in an upward direction from the first plane,
wherein a distance between the first side surfaces facing each other in the width direction is constant, and
wherein a distance between the second side surfaces facing each other in the width direction in the plurality of first parts is longer than a distance between the second side surfaces facing in the width direction in the second part.

4. The light emitting element of claim 3, wherein at least a portion of the second side surface of the second part is disposed inside the second side surface of the first part.

5. The light emitting element of claim 3, wherein a shortest distance between the first side surface and the second side surface on one side of the light emitting element is equal to or substantially equal to a shortest distance between the first side surface and the second side surface on another side of the light emitting element in the width direction.

6. The light emitting element of claim 3, wherein a shortest distance between the first side surface and the second side surface on one side of the light emitting element is smaller than a shortest distance between the first side surface and the second side surface on another side of the light emitting element in the width direction.

7. The light emitting element of claim 6, wherein an inclination angle of the second side surface of at least one of the plurality of first parts on the one side is larger than an inclination angle of the second side surface of the at least one of the plurality of first parts on the another side.

8. The light emitting element of claim 6, wherein an inclination angle of the second side surface of the second part on the one side is equal to or substantially equal to an inclination angle of the second side surface of the second part on the another side.

9. The light emitting element of claim 6, wherein the second part is one of a plurality of second parts, and
wherein the plurality of first parts and the plurality of second parts are alternately disposed.

10. The light emitting element of claim 6, wherein the second part has point symmetry shape with respect to a center of the active layer.

11. The light emitting element of claim 6, wherein the second side surface of the second part disposed on one side of the light emitting element is disposed on a same plane as the second side surface of one of the plurality of first parts, and
wherein the second side surface of the second part disposed on the another side of the light emitting element is disposed on a same plane as the second side surface of another of the plurality of first parts.

12. The light emitting element of claim 6, wherein the active layer includes a third part disposed between the plurality of first parts, the third part having a third width smaller than the second width in the width direction.

13. The light emitting element of claim 6, wherein the second width increases as a distance away from a center of the second part increases.

14. The light emitting element of claim 1, further comprising:
an encapsulation film covering a top surface and a side surface of the light emitting element,
wherein the encapsulation film covers all side surfaces of the second semiconductor layer and all side surfaces of the active layer, and covers a portion of a side surface of the first semiconductor layer.

15. A display device, comprising:
a plurality of light emitting elements disposed on a substrate,
wherein each of the plurality of light emitting elements includes:
a first semiconductor layer;
a first electrode and an active layer disposed on the first semiconductor layer;
a second semiconductor layer on the active layer; and
a second electrode disposed on the second semiconductor layer, the second electrode being apart from the first electrode,
wherein the active layer includes:
a first part having a first width; and
a second part having a same width as a width of the first part in longitudinal direction and having a second width smaller than the first width in a width direction.

16. The display device of claim 15, wherein each of the plurality of light emitting elements further includes:
a first side surface disposed below the first electrode; and
a second side surface disposed above the first electrode, the second side surface being spaced apart from the first side surface,
wherein the second side surface of the first part includes at least one surface having different inclination angles, and
wherein the second side surface of the second part has a same inclination angle.

17. The display device of claim 16, wherein the active layer is disposed closer to a first side of the light emitting element than a second side of the light emitting element that is opposite to the first side.

18. A light emitting element, comprising:
a first semiconductor layer;
a first electrode disposed on the first semiconductor layer;
an active layer disposed on the first semiconductor layer, the active layer being spaced apart from the first electrode;
a second semiconductor layer disposed on the active layer; and
a second electrode disposed on the second semiconductor layer,
wherein a first part of the active layer between the first electrode and the second electrode is wider than a second part of the active layer between the first electrode and the second electrode.

19. The light emitting element of claim 18, wherein a width of the active layer varies in a region between the first electrode and the second electrode.

20. The light emitting element of claim 18, wherein the second semiconductor layer, the active layer and a portion of the first semiconductor layer form a stacked structure having a mesa shape, and
wherein opposite sides of the mesa shape have a same angle of inclination, or
wherein the opposite sides of the mesa shape have different angles of inclination.

21. The light emitting element of claim 20, wherein the mesa shape is disposed closer to a first side of the light emitting element than a second side of the light emitting element.

22. The light emitting element of claim 18, wherein a third part of the active layer between the first electrode and the second electrode has a third width that is smaller than the first width of the first part and the second width of the second part.

23. The light emitting element of claim 18, wherein the active layer includes a first notched portion on a first side of the active layer and a second notched portion on a second side of the active layer, the second side being opposite to the first side, and
wherein the first notched portion and the second notched portion have point symmetry with respect to a center of the active layer in a plan view.
